(19) United States
(12) Patent Application Publication
(10) Pub. No.: US 2024/0261912 A1
(43) Pub. Date: Aug. 8, 2024

(54) PARTS MOUNTING SYSTEM

(71) Applicant: YAMAHA HATSUDOKI KABUSHIKI KAISHA, Iwata-shi, Shizuoka (JP)

(72) Inventors: Tsutomu YANAGIDA, Iwata-shi (JP); Yoshinori OKAMOTO, Iwata-shi (JP); Yusuke KOBAYASHI, Iwata-shi (JP); Naoya FUJII, Iwata-shi (JP); Yoichi MATSUSHITA, Iwata-shi (JP); Shin AMANAI, Iwata-shi (JP)

(73) Assignee: YAMAHA HATSUDOKI KABUSHIKI KAISHA, Iwata-shi, Shizuoka (JP)

(21) Appl. No.: 18/566,952

(22) PCT Filed: Jul. 30, 2021
(86) PCT No.: PCT/JP2021/028479

§ 371 Date: Dec. 4, 2023

(51) Int. Cl. B23P 19/04; B25J 5/00; B25J 11/00

(52) U.S. Cl. CPC B23P 19/04; B25J 5/007; B25J 11/005

(57) ABSTRACT

A parts mounting system includes a parts mounting device in a mounting area to mount parts on a board, a robot to transport a parts unit operable to hold the parts, and a placement section in a work area in which a worker works. The work area is separate from the mounting area, to allow a plurality of parts units to be placed therein or thereon, the plurality of parts units being to be transported or having been transported by the robot.

### CROSS-REFERENCE TO RELATED APPLICATION

This application is a National Stage of International Patent Application No. PCT/JP2021/028479, filed Jul. 30, 2021, the entire content of which is incorporated herein by reference.

### BACKGROUND

### Technical Field

The present disclosure relates to a parts mounting system, and more particularly, it relates to a parts mounting system that transports a parts unit.

### Background Art

Conventionally, a parts mounting system that transports a parts unit is known. Such a parts mounting system is disclosed in Japanese Patent Laid-Open No. 2021-016009, for example.

Japanese Patent Laid-Open No. 2021-016009 discloses a parts mounting system including a unit transporter that transports feeders (parts units) and a mounting line including a parts mounter in which the feeders are arranged. In this parts mounting system, a storage that stores replacement feeders of the parts mounter is arranged in the mounting line. Furthermore, the unit transporter transports the replacement feeders from a work site at which a worker works to the storage. At the work site, the worker performs work to load the replacement feeders onto the unit transporter.

### SUMMARY

However, in Japanese Patent Laid-Open No. 2021-016009, the worker performs work to load the replacement feeders onto the unit transporter at the work site, and thus the time of the worker may be greatly restricted. In this case, the worker cannot freely go to the restroom, take a meal break, and perform other tasks other than loading feeders, and thus the time of the worker cannot be effectively used. Thus, work efficiency may decrease.

Accordingly, the present disclosure provides a parts mounting system capable of improving work efficiency by effectively using the time of a worker when transporting a parts unit using a robot.

A parts mounting system according to an aspect of the present disclosure includes a parts mounting device in a mounting area to mount parts on a board, a robot to transport a parts unit operable to hold the parts, and a placement section in a work area in which a worker works. The work area is separate from the mounting area and a storage area, to allow a plurality of parts units to be placed therein or thereon. The plurality of parts units are to be transported or having been transported by the robot, and the robot includes a first robot to transport a parts supplier as the parts unit between the work area and the parts mounting device. The work area is an area in which the worker performs work to attach a reel operable to hold the parts to the parts supplier or the worker performs work to remove the reel from the parts supplier, and the placement section includes a first placement section in the work area to allow a plurality of parts suppliers to be placed therein. The plurality of parts suppliers are to be transported or having been transported by the first robot.

The parts mounting system according to this aspect of the present disclosure includes the placement section in the work area in which the worker works, the work area being separate from the mounting area, to allow the plurality of parts units to be placed therein or thereon, the plurality of parts units being to be transported or having been transported by the robot. Accordingly, the placement section can be provided as a buffer for the parts units, and thus the worker is less likely to be forced to spend time to deliver the parts unit to the robot or receive the parts unit from the robot, for example. Consequently, the worker is relatively free to go to the restroom, take a meal break, and perform other tasks, for example, unlike a case in which the time of the worker is greatly restricted, and thus when the parts unit is transported by the robot, the time of the worker can be effectively used to improve work efficiency. Furthermore, the placement section is provided in the work area, and thus unlike a case in which the placement section is provided in a mounting line, the placement section can be used as a common placement section for a plurality of mounting lines when the plurality of mounting lines are present.

In the parts mounting system according to this aspect, the first placement section can be provided as a buffer for the parts suppliers, and thus the worker is not forced to spend much time to deliver the parts supplier to the first robot or receive the parts supplier from the first robot, for example. Consequently, the worker can effectively use his or her time to improve work efficiency.

In this case, the first placement section preferably includes a replenishment stock section to allow the plurality of parts suppliers to be placed therein, the plurality of parts suppliers being to be transported from the work area to the parts mounting device and supplied to the parts mounting device by the first robot, the plurality of parts suppliers being to be used, and a collection stock section to allow a plurality of used parts suppliers to be placed therein, the plurality of used parts suppliers having been collected from the parts mounting device and transported to the work area by the first robot. Accordingly, the replenishment stock section can be provided as a buffer for the parts suppliers to be supplied, and thus the worker is not forced to spend much time to deliver the parts supplier to the first robot. Furthermore, the collection stock section can be provided as a buffer for the collected parts suppliers, and thus the worker is not forced to spend much time to receive the parts supplier from the first robot. Consequently, the worker can more effectively use his or her time to improve work efficiency. Furthermore, when the replenishment stock section is provided as a buffer for the parts suppliers to be supplied, the worker can perform work to prepare the parts supplier in a relatively flexible manner. Consequently, variations in the time required for the work to prepare the parts supplier can be absorbed.

In the structure in which the placement section includes the first placemen section, the first placement section is preferably operable to perform a placement location management to manage a presence or absence and a placement location of the parts supplier in the first placement section. Accordingly, the first placement section can manage the placement location of the parts supplier. Consequently, the progress of supplying the parts supplier to the parts mounting device can be managed.

In this case, the first placement section preferably includes a plurality of placement lanes, each to allow the parts supplier to be placed therein, and a parts supplier communicator in each of the plurality of placement lanes, and is preferably operable to perform the placement location management by communicating with the parts supplier through the parts supplier communicator. Accordingly, it can be known which parts supplier is placed in which placement lane among the plurality of placement lanes through the parts supplier communicator. Consequently, the placement location of the parts supplier can be easily managed by the first placement section.

In the structure in which the first placement section is operable to perform the placement location management, the parts mounting system is preferably operable to notify the worker of a warning when it is detected by the placement location management that the parts supplier has not been placed in the first placement section by a predetermined time before the parts mounting device runs out of the parts. Accordingly, from the warning, it can be recognized that supply of the parts supplier to the parts mounting device is delayed. Consequently, even when supply of the parts supplier to the parts mounting device is delayed, the parts supplier can be supplied to the parts mounting device in time.

The parts mounting system according to this aspect preferably further includes an automated storage in the storage area separate from the mounting area and the work area to unload a parts rack as the parts unit, the robot preferably includes a second robot to transport the parts rack between the automated storage and the work area, and the placement section preferably includes a second placement section to allow a plurality of parts racks to be placed thereon, the plurality of parts racks having been transported or being to be transported by the second robot. Accordingly, the second placement section can be provided as a buffer for the parts racks, and thus the worker is not forced to spend much time to deliver the parts rack to the second robot or receive the parts rack from the second robot, for example. Consequently, the worker can effectively use his or her time to improve work efficiency.

In this case, the second placement section preferably includes a rack placement section to allow the plurality of parts racks holding the parts to be placed thereon, the plurality of parts racks having been transported from the automated storage to the work area by the second robot, and an empty rack placement section to allow a plurality of empty parts racks not holding the parts to be placed thereon, the plurality of empty parts racks being to be collected from the work area and transported to the automated storage by the second robot. Accordingly, the rack placement section can be provided as a buffer for the parts racks, and thus the worker is not forced to spend much time to receive the parts rack from the second robot. Furthermore, the empty rack placement section can be provided as a buffer for the empty parts racks, and thus the worker is not forced to spend much time to deliver the empty parts rack to the second robot. Consequently, the worker can more effectively use his or her time to improve work efficiency.

The parts mounting system according to this aspect is preferably operable to create a plan for replenishing the parts mounting device with the parts based on information regarding a time at which the parts mounting device runs out of the parts. Accordingly, the parts mounting device can be replenished with the parts according to the plan in a planned manner, and thus it is possible to easily respond to parts replenishment rush, and the number of robots operating to supply the parts can be optimized (minimized).

In this case, the parts mounting system preferably further includes an automated storage in a storage area separate from the mounting area and the work area to unload the parts unit, and is preferably operable to calculate work times of the robot, the automated storage, and the worker, and create the plan including target work completion times for the robot, the automated storage, and the worker by performing back calculation from the time at which the parts mounting device runs out of the parts based on calculated work times. Accordingly, the robot, the automated storage, and the worker can easily know the target work completion times based on the plan, and thus they can easily complete their work by the target work completion times. Consequently, stopping of the parts mounting device due to parts runout of the parts mounting device can be easily reduced or prevented.

In the structure in which the plan is created, the parts mounting system is preferably operable to create a work group for a plurality of parts replacement rounds of the robot, and create the plan for a created work group. Accordingly, the plan can be created for each work group, and thus an excessive increase in the contents of the plan can be easily reduced or prevented. Furthermore, the plan can be created for each work group, and thus the progress of the plan for each work group can be easily managed.

According to the present disclosure, as described above, it is possible to provide the parts mounting system capable of improving work efficiency by effectively using the time of the worker when transporting the parts unit using the robot.

### BRIEF DESCRIPTION OF THE DRAWINGS

FIG. 1 is diagram showing a parts mounting system according to an embodiment of the present disclosure;

FIG. 2 is a diagram showing a parts mounting device according to the embodiment of the present disclosure;

FIG. 3 is a diagram showing a parts supplier according to the embodiment of the present disclosure;

FIG. 4 is a diagram showing a stock section and a replacement robot according to the embodiment of the present disclosure;

FIG. 5 is a block diagram showing the stock section according to the embodiment of the present disclosure;

FIG. 6 is a block diagram showing the replacement robot according to the embodiment of the present disclosure;

FIG. 7 is a diagram for illustrating transportation of the parts supplier by the replacement robot according to the embodiment of the present disclosure;

FIG. 8 is a diagram for illustrating preparation of the parts supplier according to the embodiment of the present disclosure;

FIG. 9 is a diagram for illustrating placement of the parts supplier in the stock section according to the embodiment of the present disclosure;

FIG. 10 is a diagram for illustrating acquisition of the parts supplier from the stock section according to the embodiment of the present disclosure;

FIG. 11 is a diagram for illustrating replenishment of the parts mounting device with the parts supplier according to the embodiment of the present disclosure;

FIG. 12 is a diagram for illustrating return of the parts supplier to the stock section according to the embodiment of the present disclosure;

FIG. 13 is a diagram showing a transport robot and an automated storage according to the embodiment of the present disclosure;

FIG. 14 is a diagram showing a rack placement section according to the embodiment of the present disclosure;

FIG. 15 is a block diagram showing the transport robot according to the embodiment of the present disclosure;

FIG. 16 is a block diagram showing the automated storage according to the embodiment of the present disclosure;

FIG. 17 is a block diagram showing the rack placement section according to the embodiment of the present disclosure;

FIG. 18 is a diagram for illustrating transportation of a parts rack by the transport robot according to the embodiment of the present disclosure;

FIG. 19 is a block diagram showing a management device according to the embodiment of the present disclosure;

FIG. 20 is a diagram (1) for illustrating control of each device by the management device according to the embodiment of the present disclosure;

FIG. 21 is a diagram (2) for illustrating control of each device by the management device according to the embodiment of the present disclosure;

FIG. 22 is a flowchart for illustrating a control process of parts replenishment according to the embodiment of the present disclosure;

FIG. 23 is a diagram for illustrating a parts runout prediction list according to the embodiment of the present disclosure;

FIG. 24 is a diagram for illustrating a parts unloading/transportation list, a tape setup worker instruction list, and a replenishment instruction list according to the embodiment of the present disclosure;

FIG. 25 is a diagram for illustrating management by automated storage management software and management by transport robot management software based on the parts unloading/transportation list according to the embodiment of the present disclosure;

FIG. 26 is a diagram for illustrating management by stock section management software based on the tape setup worker instruction list according to the embodiment of the present disclosure;

FIG. 27 is a diagram for illustrating management by replacement robot management software based on the replenishment instruction list according to the embodiment of the present disclosure; and

FIG. 28 is a flowchart for illustrating a control process of warning during parts replenishment according to the embodiment of the present disclosure.

### DETAILED DESCRIPTION

An embodiment embodying the present disclosure is hereinafter described on the basis of the drawings.

### Structure of Parts Mounting System

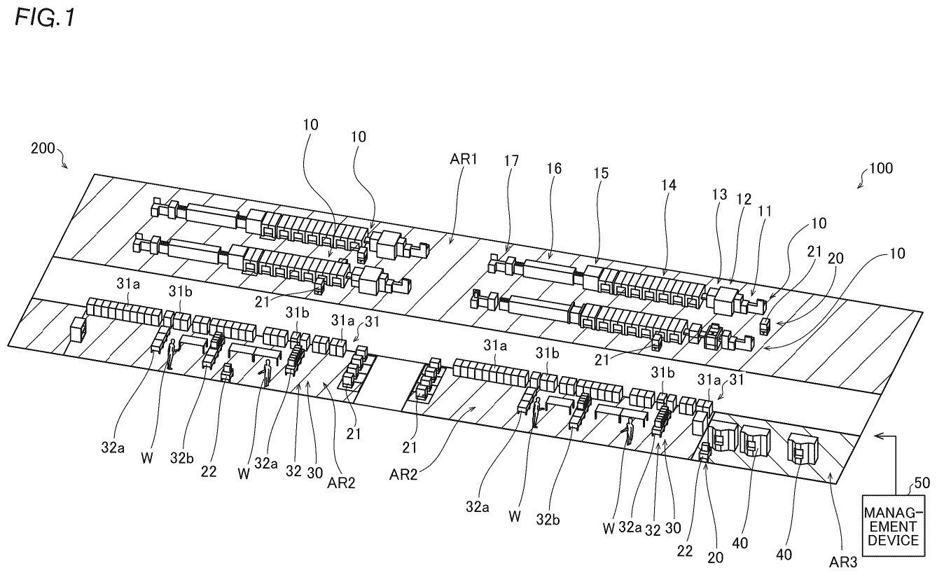

The structure of a parts mounting system 100 according to the embodiment of the present disclosure is now described with reference to FIG. 1.

The parts mounting system 100 according to this embodiment mounts parts on a board S to manufacture the board S on which the parts have been mounted, as shown in FIG. 1. The board S is a printed circuit board on which conductor wiring is formed. The parts are electronic parts such as LSIs, ICs, transistors, capacitors, and resistors.

The parts mounting system 100 is provided in a parts mounting factory 200. In the parts mounting factory 200 according to this embodiment, a mounting area ARI for manufacturing the board S on which the parts have been mounted, work areas AR2 for workers W to work, and a storage area AR3 for storing the parts are provided. The parts are transported from the storage area AR3 to the work areas AR2. After work is performed on the parts by the workers W in the work areas AR2, the parts are transported to the mounting area AR1 and are mounted on the board S in the mounting area AR1. The mounting area AR1, the work areas AR2, and the storage area AR3 are separate from each other. In the parts mounting factory 200 according to this embodiment, one mounting area AR1 and one storage area AR3 are provided, and a plurality of (two) work areas AR2 are provided.

The parts mounting system 100 includes mounting lines 10, robots 20, placement sections 30, automated storages 40, and a management device 50. The mounting lines 10 are placed in the mounting area AR1. The placement sections 30 are placed in the work areas AR2. The automated storages 40 are placed in the storage area AR3. The management device 50 may be placed in a management area separate from the mounting area AR1, the work areas AR2, and the storage area AR3, or may be placed in any one of the mounting area AR1, the work areas AR2, and the storage area AR3.

A plurality of (four) mounting lines 10 are provided in the mounting area AR1. The mounting lines 10 each include a loader 11, a printer 12, a printing inspection machine 13, parts mounting devices 14, a visual inspection device 15, a reflow device 16, and an unloader 17. In the mounting line 10, the board S is conveyed from the upstream side to the downstream side along a production line.

The loader 11 has a function of holding the board (wiring board) S before the parts are mounted and carrying the board S into the mounting line 10.

The printer 12 is a screen printer and has a function of applying cream solder on a mounting surface of the board S.

The printing inspection machine 13 has a function of inspecting the state of the cream solder printed by the printer 12.

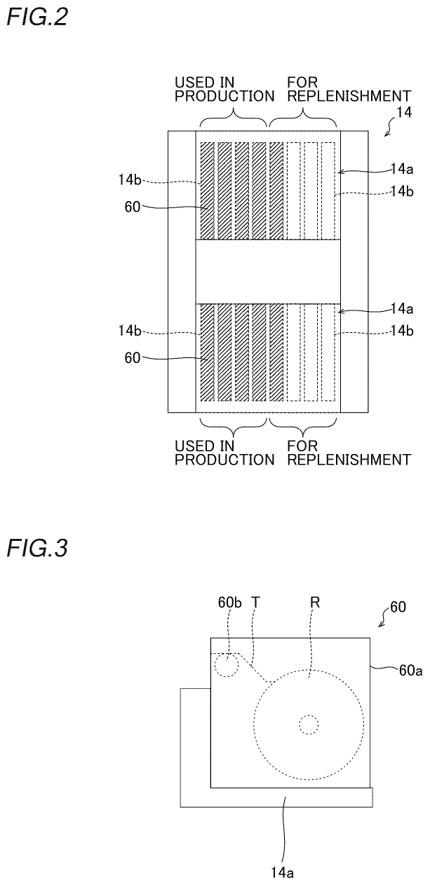

The parts mounting devices 14 have a function of mounting the parts at predetermined mounting positions on the board S on which the cream solder has been printed. A plurality of parts mounting devices 14 are provided along the conveyance direction of the board S. The plurality of parts mounting devices 14 have the same or similar structures. As shown in FIG. 2, the parts mounting devices 14 each include feeder banks 14a in which a plurality of parts suppliers 60 can be horizontally arranged. The feeder banks 14a each include a plurality of placement lanes 14b, each of which allows a parts supplier 60 to be placed therein. The parts supplier 60 is attached to the placement lane 14b to be removable from the placement lane 14b by being slid. The parts mounting device 14 mounts the parts on the board S using the parts supplier 60. The parts supplier 60 is an example of a “parts unit” in the claims.

Two parts suppliers 60 that supply the same type of parts are placed in the parts mounting device 14 such that it is possible to perform alternate operation to switch to the parts supplier 60 for replenishment and continue supply of the same type of parts when the parts supplier 60 used in the production runs out of the parts. That is, the parts supplier 60 used in the production and the parts supplier 60 for replenishment are placed in the plurality of placement lanes 14b. Thus, the parts supplier 60 for replenishment can be placed in advance, and thus it is possible to reduce or prevent the occurrence of a replenishment rush in which parts replenishment is busy and to perform parts replenishment smoothly. The parts mounting device 14 does not need to be able to perform the alternate operation. In this case, when the parts supplier 60 used in the production has run out of the parts, the parts supplier 60 that has run out of the parts may be replaced with a new parts supplier 60.

As shown in FIG. 3, the parts supplier 60 is a tape feeder that supplies the parts with a parts supply tape T holding the parts. Specifically, the parts supplier 60 is a cassette feeder including a cassette-type main body 60a. The parts supplier 60 includes a reel R that holds the parts supply tape T, and a drive mechanism 60b including a sprocket, gears, etc. to feed the parts supply tape T, in the cassette-type main body 60a.

As shown in FIG. 1, the visual inspection device 15 has a function of inspecting the appearance of the board S on which the parts have been mounted by the parts mounting devices 14.

The reflow device 16 has a function of melting the solder by performing a heat treatment and joining the parts to electrode portions of the board S.

The unloader 17 has a function of discharging the board S on which the parts have been mounted from the mounting line 10.

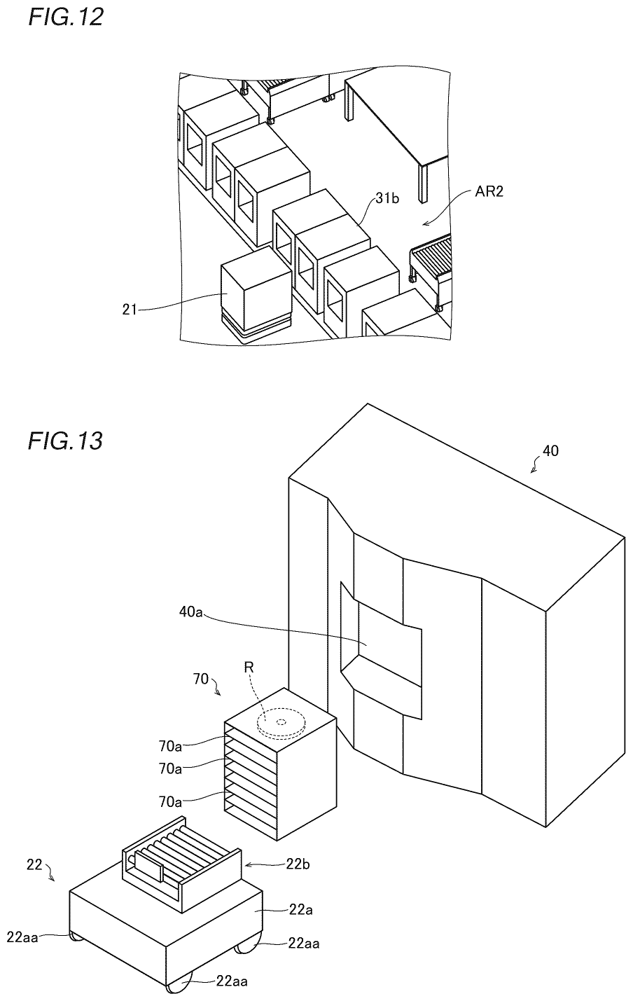

The robots 20 transport parts units that can hold the parts. Specifically, the robots 20 include replacement robots 21 and transport robots 22. The replacement robots 21 transport the parts suppliers 60 as the parts units between the work areas AR2 and the parts mounting devices 14. The transport robots 22 transport parts racks 70 (see FIG. 13), which are described below, as the parts units, between the automated storages 40 and the work areas AR2. A plurality of replacement robots 21 and a plurality of transport robots 22 are provided in the parts mounting factory 200. The replacement robots 21, the transport robots 22, and the parts racks 70 are examples of a “first robot”, a “second robot”, and a “parts unit” in the claims, respectively. The structures of the replacement robots 21 and the transport robots 22 are described below in detail.

In this embodiment, a plurality of parts units to be transported or having been transported by the robots 20 can be placed in or on the placement sections 30. Specifically, the placement sections 30 include first placement sections 31 and second placement sections 32. In this embodiment, a plurality of parts suppliers 60 as the parts units to be transported or having been transported by the replacement robots 21 can be placed in the first placement sections 31. Furthermore, in this embodiment, the first placement sections 31 include replenishment stock sections 31a in which a plurality of parts suppliers 60 to be used, which are to be transported from the work areas AR2 to the parts mounting devices 14 and supplied to the parts mounting devices 14 by the replacement robots 21, can be placed, and collection stock sections 31b in which a plurality of used parts suppliers 60, which the replacement robots 21 have collected from the parts mounting devices 14 and transported to the work areas AR2, can be placed. A plurality of replenishment stock sections 31a and a plurality of collection stock sections 31b are provided in the work areas AR2. The structures of the replenishment stock sections 31a and the collection stock sections 31b are described below in detail.

In this embodiment, a plurality of parts racks 70 as the parts units having been transported or to be transported by the transport robots 22 can be placed on the second placement sections 32. Furthermore, in this embodiment, the second placement sections 32 include rack placement sections 32a on which a plurality of parts racks 70 holding the parts, which the transport robots 22 have transported from the automated storages 40 to the work areas AR2, can be placed, and empty rack placement sections 32b on which a plurality of empty parts racks 70 not holding the parts, which are to be collected from the work areas AR2 and transported to the automated storages 40 by the transport robots 22, can be placed. A plurality of rack placement sections 32a and a plurality of empty rack placement sections 32b are provided in the work areas AR2. The structures of the rack placement sections 32a and the empty rack placement sections 32b are described below in detail.

In this embodiment, the placement sections 30 (the replenishment stock sections 31a, the collection stock sections 31b, the rack placement sections 32a, and the empty rack placement sections 32b) are provided as common placement sections for the plurality of mounting lines 10.

The automated storages 40 store the parts and the parts racks 70 as the parts units, and unload the parts racks 70 holding the parts. A plurality of automated storages 40 are provided in the storage area AR3. The structures of the automated storages 40 are described below in detail.

The management device 50 is one or more computers that manage the parts mounting system 100. The structure of the management device 50 is described below in detail.

### Structures of Stock Sections and Replacement Robots

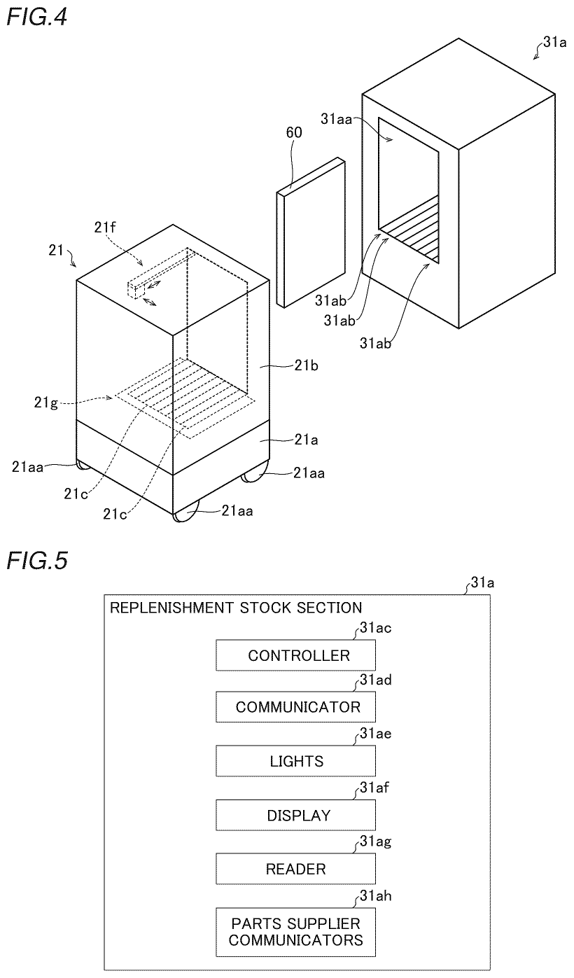

The structures of the replenishment stock sections 31a, the collection stock sections 31b, and the replacement robots 21 are now described with reference to FIGS. 4 to 6.

As shown in FIG. 4, each of the replenishment stock sections 31 a is a shelf including a storage 31aa in which a plurality of parts suppliers 60 can be horizontally arranged. The replenishment stock sections 31a are provided as temporary storages in which the parts suppliers 60 to be used, which are to be transported and supplied to (mounted on) the parts mounting devices 14 by the replacement robots 21, are temporarily placed. The storage 31aa includes a plurality of placement lanes 31ab, each of which allows a parts supplier 60 to be placed therein. The parts supplier 60 is attached to the placement lane 31ab to be removable from the placement lane 31ab by being slid. In the replenishment stock sections 31a, the parts suppliers 60 to be supplied to the parts mounting devices 14 are prepared and placed by the workers W. Then, the parts suppliers 60 placed in the replenishment stock sections 31a are acquired by the replacement robots 21 and transported to the parts mounting devices 14.

As shown in FIG. 5, each of the replenishment stock sections 31a includes a controller 31ac, a communicator 31ad, lights 31ae, a display 31af, a reader 31ag, and parts supplier communicators 31ah. The controller 31ac includes a control circuit that controls the operation of the replenishment stock section 31a. Furthermore, the controller 31ac includes a processor to execute a predetermined program and a memory to store the predetermined program. The communicator 31ad is communicable with each device of the parts mounting system 100, such as the management device 50. The communicator 31ad communicates by wireless communication, for example. The lights 31ae each include a light source such as an LED, and turn on and emit light under the control of the controller 31ac. Furthermore, the lights 31ae are provided at positions corresponding to the plurality of placement lanes 31ab, respectively, and function as indicators to notify the workers W that the parts suppliers 60 have been attached to the placement lanes 31ab.

The display 31af is a monitor such as a liquid crystal monitor, and can display information. The reader 31ag is a barcode reader that reads a barcode attached to the parts supplier 60 and including information representing the ID of the parts supplier 60. The parts supplier communicators 31ah are provided in the plurality of placement lanes 31ab, respectively. The parts supplier communicators 31ah communicably connect the parts suppliers 60 placed in the placement lanes 31ab and the replenishment stock section 31a. The controller 31ac can detect the parts suppliers 60 placed in the placement lanes 31ab based on the communication states with the parts suppliers 60 by the parts supplier communicators 31ah.

In this embodiment, the replenishment stock section 31a as the first placement section 31 can perform a placement location management (location management) to manage the presence or absence and the placement location of the parts supplier 60 in the replenishment stock section 31a as the first placement section 31. Specifically, the replenishment stock section 31a as the first placement section 31 can perform the placement location management by communicating with the parts supplier 60 through the parts supplier communicator 31ah. The replenishment stock section 31a as the first placement section 31 acquires the ID of the parts supplier 60 stored in the memory of the parts supplier 60 by communicating with the parts supplier 60 through the parts supplier communicator 31ah. Thus, the replenishment stock section 31a as the first placement section 31 can detect which ID of the parts supplier 60 is placed in which placement lane 31ab.

In this embodiment, the management device 50 notifies the worker W of a warning when it is detected that the parts supplier 60 has not been placed in the replenishment stock section 31a as the first placement section 31 by a predetermined time before the parts mounting device 14 runs out of the parts by the placement location management in the replenishment stock section 31a as the first placement section 31. The warning notification is described below in detail.

The used parts suppliers 60 collected from the parts mounting devices 14 are returned to the collection stock sections 31b. The collection stock sections 31b are provided as temporary storages in which the used parts suppliers 60 collected by the replacement robots 21 are temporarily placed. The collection stock sections 31b have similar structures to the replenishment stock sections 31a, except that the collection stock sections 31b are shelves on which the used parts suppliers 60 are placed. Therefore, although detailed description thereof is omitted, the collection stock sections 31b each include a storage 31aa, a plurality of placement lanes 31ab, a controller 31ac, a communicator 31ad, lights 31ae, a display 31af, a reader 31ag, and parts supplier communicators 31ah.

As shown in FIG. 4, the replacement robots 21 are autonomous robots. The replacement robots 21 transport the parts suppliers 60 between the parts mounting devices 14 and both the replenishment stock sections 31a and the collection stock sections 31b. The replacement robots 21 transport the parts suppliers 60 to be used, which have been acquired from the replenishment stock sections 31a, to the parts mounting devices 14. Furthermore, the replacement robots 21 transport the used parts suppliers 60, which have been collected from the parts mounting devices 14, to the collection stock sections 31b.

The replacement robots 21 each include a traveling unit 21a and a storage 21b provided on the traveling unit 21a. The traveling unit 21a includes a plurality of wheels 21aa as drive wheels that are rotationally driven by a motor, and autonomously travels. The traveling unit 21a is an automatic guided vehicle (AGV), for example. The storage 21b can store a plurality of parts suppliers 60 horizontally arranged. The storage 21b includes a plurality of placement lanes 21c, each of which allows a parts supplier 60 to be placed therein. The parts supplier 60 is attached to the placement lane 21c to be removable from the placement lane 21c by being slid. The placement lanes 31ab of the replenishment stock section 31a, the placement lanes 21c of the replacement robot 21, and the placement lanes 14b of the parts mounting device 14 are provided so as to correspond to each other.

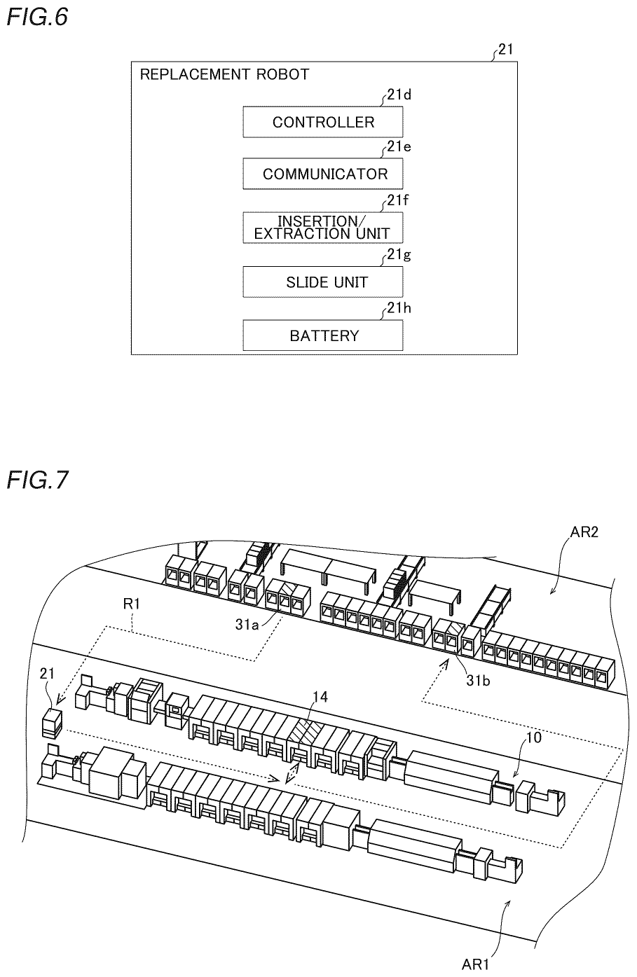

As shown in FIG. 6, the replacement robot 21 further includes a controller 21d, a communicator 21e, an insertion/extraction unit 21f, a slide unit 21g, and a battery 21h. The controller 21d includes a control circuit that controls the operation of the replacement robot 21. Furthermore, the controller 21d includes a processor to execute a predetermined program and a memory to store the predetermined program. The communicator 21e communicates with each device of the parts mounting system 100, such as the management device 50. The communicator 21e communicates by wireless communication, for example.

As shown in FIG. 4, the insertion/extraction unit 21f draws the parts supplier 60 into the storage 21b or pushes the parts supplier 60 out of the storage 21b under the control of the controller 21d. The insertion/extraction unit 21f extracts the parts supplier 60 from the placement lane 31ab of the storage 31aa of the replenishment stock section 31a and pulls it into the placement lane 21c of the storage 21b to collect the parts supplier 60 from the replenishment stock section 31a into the replacement robot 21. Furthermore, the insertion/extraction unit 21f pushes the parts supplier 60 out of the placement lane 21c of the storage 21b and inserts it into the placement lane 14b of the parts mounting device 14 to supply the parts supplier 60 from the replacement robot 21 to the parts mounting device 14.

The insertion/extraction unit 21f extracts the parts supplier 60 from the placement lane 14b of the parts mounting device 14 and pulls it into the placement lane 21c of the storage 21b to collect the parts supplier 60 from the parts mounting device 14 to the replacement robot 21. Furthermore, the insertion/extraction unit 21f pushes the parts supplier 60 out of the placement lane 21c of the storage 21b and inserts it into the placement lane 31ab of the storage 31aa of the collection stock section 31b to return the parts supplier 60 from the replacement robot 21 to the collection stock section 31b. The insertion/extraction unit 21f includes a feeding mechanism such as a ball screw mechanism that can insert and extract (push and pull) the parts supplier 60, and a motor that drives the feeding mechanism.

The slide unit 21g slides the plurality of placement lanes 21c in a horizontal direction in which the plurality of placement lanes 21c are aligned. The slide unit 21g includes a feeding mechanism such as a ball screw mechanism that can slide the plurality of placement lanes 21c, and a motor that drives the feeding mechanism. The battery 21h is a secondary battery that supplies power to each portion of the replacement robot 21. The replacement robot 21 is driven by the power supplied from the battery 21h.

### Transportation Operation of Replacement Robot

The operation of the replacement robot 21 to transport the parts supplier 60 is now described with reference to FIGS. 7 to 12. The operation of the replacement robot 21 to transport the parts supplier 60 is performed when the parts mounting device 14 runs out of the parts.

As shown in FIG. 7, the replacement robot 21 transports the parts supplier 60 so as to circulate along a circulation line R1 based on an instruction from the management device 50. The circulation line R1 is a route from the replenishment stock section 31a to the collection stock section 31b via the parts mounting device 14. Furthermore, the circulation line R1 is a route including movement between the work area AR2 and the mounting area AR1. The replacement robot 21 acquires the parts supplier 60 from the replenishment stock section 31a and replenishes the parts mounting device 14 with the acquired parts supplier 60 while moving along the circulation line R1. Furthermore, the replacement robot 21 collects the parts supplier 60 that has run out of the parts from the parts mounting device 14 and returns the collected parts supplier 60 to the collection stock section 31b while moving along the circulation line R1.

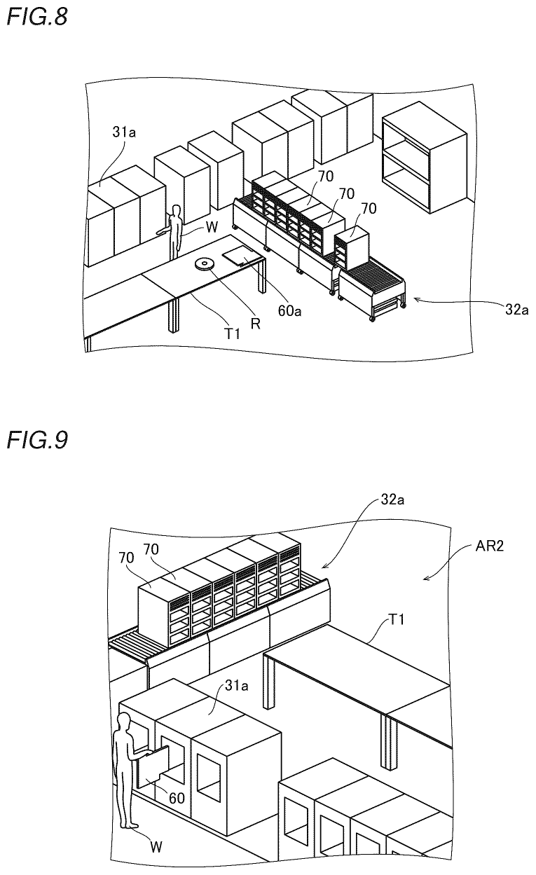

As a preliminary preparation, as shown in FIG. 8, the worker W prepares the parts supplier 60 to be transported by the replacement robot 21 in the work area AR2. Specifically, the worker W acquires a reel R from the parts rack 70 described below and performs work to attach the acquired reel R into the main body 60a of the parts supplier 60 to which the reel R has not been attached. Thus, the worker W prepares the parts supplier 60 with the reel R attached inside the main body 60a. At this time, the worker W performs work to prepare the parts supplier 60 on a work desk T1, for example.

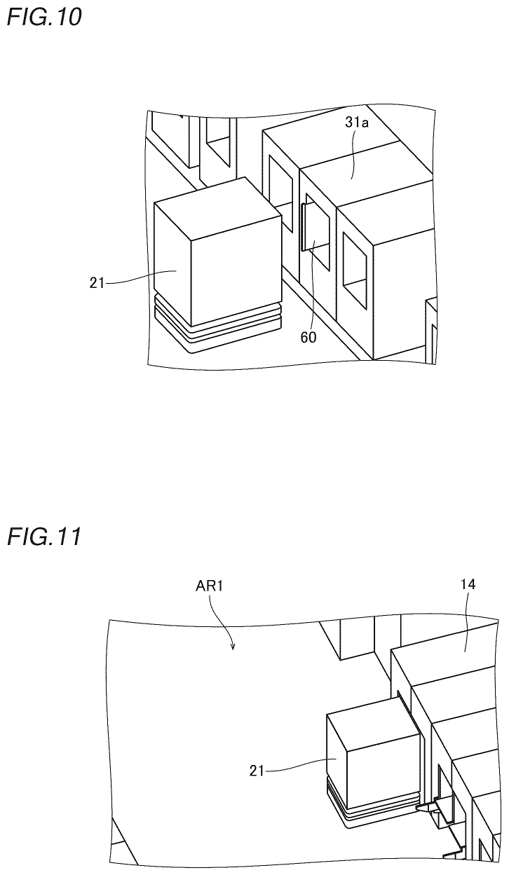

Then, as shown in FIG. 9, the worker W places the prepared parts supplier 60 in a predetermined placement lane 31ab of the replenishment stock section 31a. In this manner, the parts supplier 60 is placed in the replenishment stock section 31a, and thus the worker W does not need to deliver the parts supplier 60 to the replacement robot 21.

Then, as shown in FIG. 10, the replacement robot 21 moves in front of the replenishment stock section 31a in which the parts supplier 60 has been placed by the worker W. Then, the replacement robot 21 pulls the parts supplier 60 from the placement lane 31ab of the replenishment stock section 31a into the placement lane 21c using the insertion/extraction unit 21f to acquire the parts supplier 60.

Then, as shown in FIG. 11, the replacement robot 21 moves along the circulation line R1 in front of the parts mounting device 14 that requires the parts supplier 60 (i.e., the parts mounting device 14 that has run out of the parts). Then, the replacement robot 21 pushes the parts supplier 60 to be used out of the placement lane 21c to the placement lane 14b of the parts mounting device 14 using the insertion/extraction unit 21f to replenish the parts mounting device 14 with the parts supplier 60, and pulls the parts supplier 60 that has run out of the parts from the placement lane 14b of the parts mounting device 14 into the placement lane 21c using the insertion/extraction unit 21f to acquire the parts supplier 60. Thus, the parts supplier 60 that has run out of the parts is replaced with a new parts supplier 60 holding the parts.

Then, as shown in FIG. 12, the replacement robot 21 moves in front of the predetermined collection stock section 31b along the circulation line R1. Then, the replacement robot 21 pushes the parts supplier 60, which has run out of the parts, out of the placement lane 21c into the predetermined placement lane 31ab of the collection stock section 31b using the insertion/extraction unit 21f to return the parts supplier 60, which has run out of the parts, to the collection stock section 31b. Then, at the predetermined timing, the worker W collects the parts supplier 60 that has run out of the parts from the collection stock section 31b, and performs work to remove the reel R (i.e., the reel R that has run out of the parts) from the main body 60a of the collected parts supplier 60. In this manner, the parts supplier 60 that has run out of the parts is placed in the collection stock section 31b, and thus the worker W does not need to receive the parts supplier 60 that has run out of the parts from the replacement robot 21.

In the above manner, the parts supplier 60 is transported by the replacement robot 21. The operation of transportation of the parts supplier 60 shown in FIGS. 7 to 12 is merely examples, and the operation of the replacement robot 21 to transport the parts supplier 60 is not particularly limited to the examples shown in FIGS. 7 to 12.

Structures of Transport robot, Rack Placement Section, and Automated Storage

The structures of the transport robot 22, the rack placement section 32a, the empty rack placement section 32b, and the automated storage 40 are now described with reference to FIGS. 13 to 17.

As shown in FIG. 13, the transport robot 22 is an autonomous robot. The transport robot 22 transports the parts rack 70 between the automated storage 40 and both the rack placement section 32a and the empty rack placement section 32b. The transport robot 22 transports the parts rack 70 holding the parts to be used, which has been acquired from the automated storage 40, to the rack placement section 32a. Furthermore, the transport robot 22 transports an empty parts rack 70 not holding the parts, which has been collected from the empty rack placement section 32b, to the automated storage 40.

The parts rack 70 is a rack that can hold a plurality of reels R that hold the parts. Specifically, the parts rack 70 includes a plurality of shelf boards 70a, each of which can hold a reel R. The plurality of shelf boards 70a are vertically arranged, and the reel R is placed on each horizontal support surface. The transport robot 22 can transport a plurality of parts (a plurality of reels R) at once by transporting the parts rack 70.

The transport robot 22 includes a traveling unit 22a and a receiving unit 22b provided on the traveling unit 22a. The traveling unit 22a includes a plurality of wheels 22aa as drive wheels that are rotationally driven by a motor, and autonomously travels. The traveling unit 22a is an automatic guided vehicle (AGV), for example. The receiving unit 22b can receive and hold the parts rack 70. Furthermore, the receiving unit 22b can deliver the held parts rack 70.

Specifically, the receiving unit 22b receives and holds the parts rack 70 holding the parts (reels R) from the automated storage 40. The receiving unit 22b delivers the parts rack 70 holding the parts (reels R) to the rack placement section 32a. The receiving unit 22b receives and holds an empty parts rack 70 not holding the parts (reels R) from the empty rack placement section 32b. The receiving unit 22b delivers the empty parts rack 70 to the automated storage 40. The receiving unit 22b includes a feeding mechanism such as a roller that can receive and deliver the parts rack 70, for example.

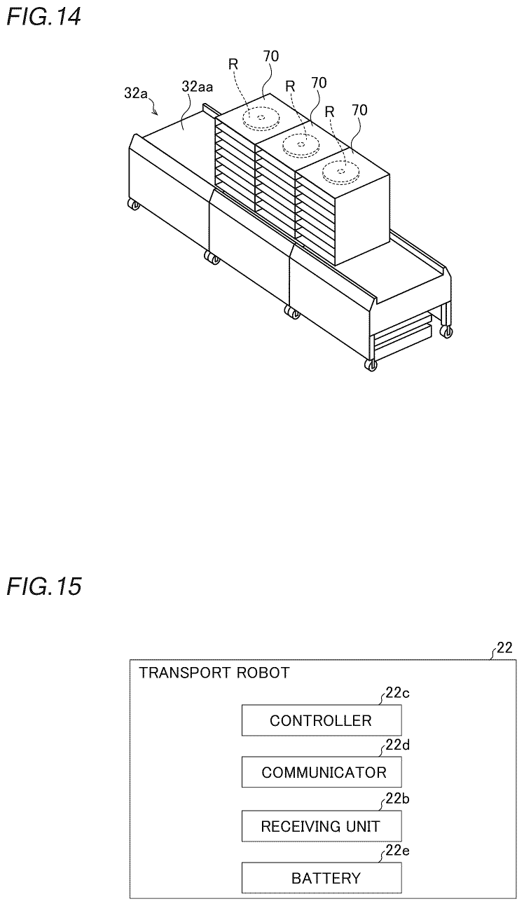

As shown in FIG. 15, the transport robot 22 further includes a controller 22c, a communicator 22d, and a battery 22e. The controller 22c includes a control circuit that controls the operation of the transport robot 22. Furthermore, the controller 22c includes a processor to execute a predetermined program and a memory to store the predetermined program. The communicator 22d communicates with each device of the parts mounting system 100, such as the management device 50. The communicator 22d communicates by wireless communication, for example. The battery 22e is a secondary battery that supplies power to each portion of the transport robot 22. The transport robot 22 is driven by the power supplied from the battery 22e.

As shown in FIG. 13, the automated storage 40 is a storage that stores reels R holding the parts and an empty parts rack 70 not holding the parts. The automated storage 40 places the reels R (parts) on the empty parts rack 70 and unloads the parts rack 70 on which the reels R (parts) have been placed. The automated storage 40 includes a loading/unloading port 40a through which the reels R and the parts rack 70 can be loaded and unloaded.

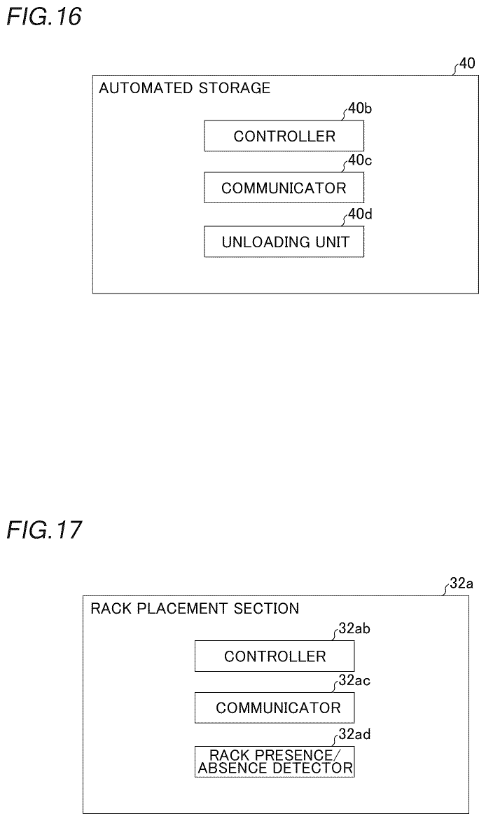

As shown in FIG. 16, the automated storage 40 further includes a controller 40b, a communicator 40c, and an unloading unit 40d. The controller 40b includes a control circuit that controls the operation of the automated storage 40. The controller 40b includes a processor to execute a predetermined program and a memory to store the predetermined program. The communicator 40c communicates with each device of the parts mounting system 100, such as the management device 50. The communicator 40c communicates by wireless communication, for example. The unloading unit 40d causes the parts rack 70 to hold the reels R (parts), and unloads the parts rack 70 holding the reels R (parts) from the loading/unloading port 40a.

As shown in FIG. 14, the rack placement section 32a is a platform having a placement portion 32aa on which a plurality of parts racks 70 can be horizontally arranged. The rack placement section 32a is provided as a temporary storage in which the parts rack 70 holding the reels R (parts) to be used and to be supplied (mounted) to the parts mounting device 14, which has been transported by the transport robot 22, is temporarily placed. The placement portion 32aa horizontally extends. The parts rack 70 is slid and placed on the placement portion 32aa. The worker W takes out the reel R from the parts rack 70 placed on the placement portion 32aa of the rack placement section 32a, and performs work to attach it to the main body 60a of the parts supplier 60. Furthermore, the worker W moves the empty parts rack 70 from which all the reels R have been taken out from the rack placement section 32a to the empty rack placement section 32b.

As shown in FIG. 16, the rack placement section 32a further includes a controller 32ab, a communicator 32ac, and a rack presence/absence detector 32ad. The controller 32abincludes a control circuit that controls the operation of the rack placement section 32a. Furthermore, the controller 32ab includes a processor to execute a predetermined program and a memory to store the predetermined program. The communicator 32ac can communicate with each device of the parts mounting system 100, such as the management device 50. The communicator 32ac communicates by wireless communication, for example. The rack presence/absence detector 32ad detects the presence or absence of the parts rack 70 on the placement portion 32aa. The rack presence/absence detector 32ad is not particularly limited, but includes, for example, a photosensor that can optically detect the presence or absence of the parts rack 70, or an operation switch that can be operated by the worker W to detect the presence or absence of the parts rack 70.

On the empty rack placement section 32b, the empty parts rack 70 from which the worker W has taken out all the reels R (parts) is placed. The empty rack placement section 32b is provided as a temporary storage in which the used empty parts rack 70 is temporarily placed. The empty rack placement section 32b has a similar structure to the rack placement section 32a, except that the empty rack placement section 32b is a platform on which the used empty parts rack 70 is placed. Therefore, although detailed description thereof is omitted, the empty rack placement section 32b includes a placement portion 32aa, a controller 32ab, a communicator 32ac, and a rack presence/absence detector 32ad.

### Transportation Operation of Transport Robot

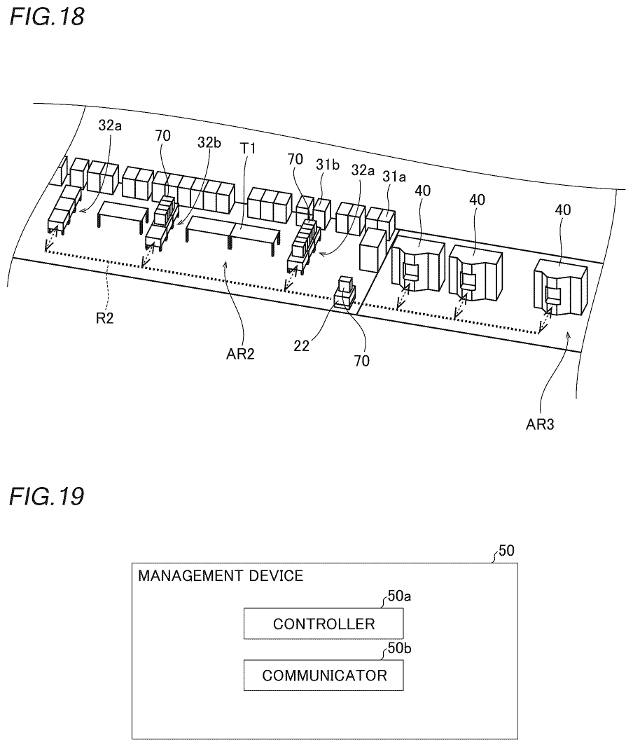

The operation of the transport robot 22 to transport the parts rack 70 is now described with reference to FIG. 18.

As shown in FIG. 18, the transport robot 22 transports the parts rack 70 along a movement line R2 based on an instruction from the management device 50. The movement line R2 is a route including movement between the automated storage 40 and both the rack placement section 32a and the empty rack placement section 32b. Furthermore, the movement line R2 is a route including movement between the storage area AR3 and the work area AR2. The transport robot 22 acquires the parts rack 70 from the automated storage 40 and places the acquired parts rack 70 on the rack placement section 32a while moving along the movement line R2. Furthermore, the transport robot 22 collects the empty parts rack 70 from the empty rack placement section 32b and returns the collected parts rack 70 to the automated storage 40 while moving along the movement line R2.

First, the automated storage 40 prepares the parts rack 70 on which the reels R are placed, and unloads the prepared parts rack 70. The transport robot 22 moves in front of the automated storage 40, and receives the parts rack 70 unloaded from the automated storage 40 using the receiving unit 22b. Then, the transport robot 22 moves in front of the predetermined rack placement section 32a along the movement line R2. Then, the transport robot 22 delivers the parts rack 70 on the receiving unit 22b to the placement portion 32aa of the rack placement section 32a using the receiving unit 22b. In this manner, the parts rack 70 is placed on the rack placement section 32a, and thus the worker W does not need to receive the parts rack 70 from the transport robot 22.

At the predetermined timing, the transport robot 22 moves in front of the empty rack placement section 32b on which the empty parts rack 70 has been placed and receives the empty parts rack 70 using the receiving unit 22b. Then, the transport robot 22 moves in front of the predetermined automated storage 40 along the movement line R2. Then, the transport robot 22 delivers the empty parts rack 70 on the receiving unit 22b to the automated storage 40 using the receiving unit 22b. In this manner, the parts rack 70 is collected from the empty rack placement section 32b, and thus the worker W does not need to deliver the empty parts rack 70 to the transport robot 22.

In the above manner, the operation of the transport robot 22 to transport the parts rack 70 is performed. The operation of transportation of the parts rack 70 shown in FIG. 18 is merely an example, and the operation of the transport robot 22 to transport the parts rack 70 is not particularly limited to the example shown in FIG. 18.

### Structure of Management Device

The structure of the management device 50 is now described with reference to FIGS. 19 to 21.

As shown in FIG. 19, the management device 50 includes a controller 50a and a communicator 50b. The controller 50a includes a control circuit that controls the operation of the parts mounting system 100. Furthermore, the controller 50a includes a processor to execute a predetermined program and a memory to store the predetermined program. The communicator 50b communicates with each device of the parts mounting system 100. The communicator 50b communicates by wireless communication, for example.

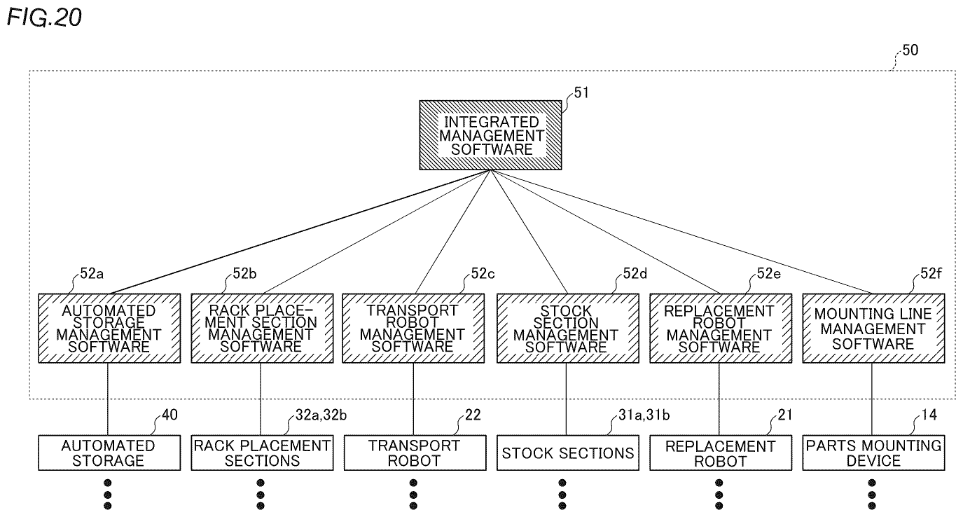

As shown in FIG. 20, the management device 50 includes, as software structures, integrated management software 51 to integrally manage each device group (a group of automated storages 40, a group of rack placement sections 32a, a group of empty rack placement sections 32b, a group of transport robots 22, a group of replenishment stock sections 31a, a group of collection stock sections 31b, a group of replacement robots 21, and a group of parts mounting devices 14) of the parts mounting system 100, and a plurality of pieces of group management software 52a to 52f to manage each device group of the parts mounting system 100. Specifically, the management device 50 includes, as group management software, automated storage management software 52a, rack placement section management software 52b, transport robot management software 52c, stock section management software 52d, replacement robot management software 52e, and mounting line management software 52f. The management device 50 may execute each software on one computer, or may execute each software on a plurality of computers.

The integrated management software 51 integrally manages each device group (a group of automated storages 40, a group of rack placement sections 32a, a group of empty rack placement sections 32b, a group of transport robots 22, a group of replenishment stock sections 31a, a group of collection stock sections 31b, a group of replacement robots 21, and a group of parts mounting devices 14) of the parts mounting system 100 via the group management software 52a to 52f.

The automated storage management software 52a manages a group of automated storages 40 including a plurality of automated storages 40 in the parts mounting factory 200. The rack placement section management software 52b manages a group of rack placement sections 32a including a plurality of rack placement sections 32a in the parts mounting factory 200, and a group of empty rack placement sections 32b including a plurality of empty rack placement sections 32b in the parts mounting factory 200. The transport robot management software 52c manages a group of transport robots 22 including a plurality of transport robots 22 in the parts mounting factory 200. The stock section management software 52d manages a group of replenishment stock sections 31a including a plurality of replenishment stock sections 31a in the parts mounting factory 200, and a group of collection stock sections 31b including a plurality of collection stock sections 31b. The replacement robot management software 52e manages a group of replacement robots 21 including a plurality of replacement robots 21 in the parts mounting factory 200. The mounting line management software 52f manages a group of parts mounting devices 14 including a plurality of parts mounting devices 14 in the parts mounting factory 200.

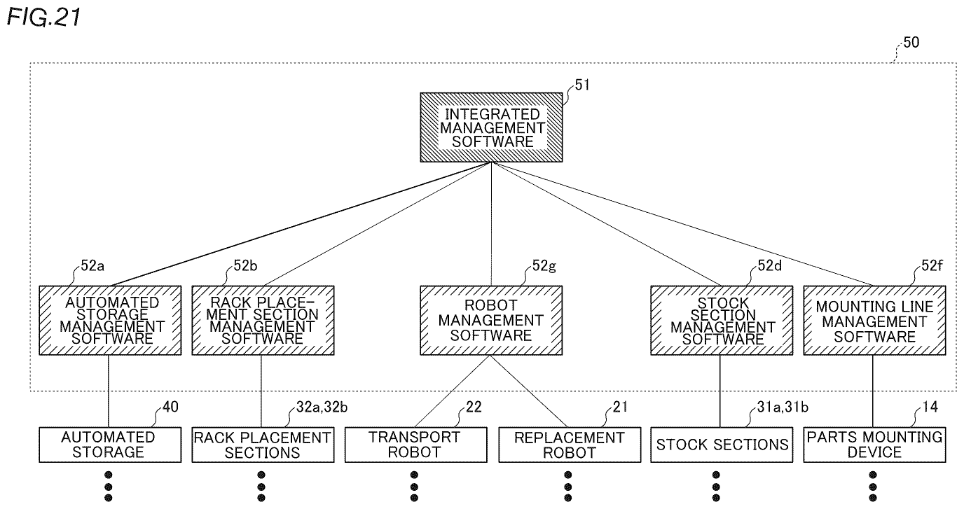

As shown in FIG. 21, the management device 50 may include robot management software 52g instead of the transport robot management software 52c and the replacement robot management software 52e. The robot management software 52g manages a group of transport robots 22 including a plurality of transport robots 22 in the parts mounting factory 200 and a group of replacement robots 21 including a plurality of replacement robots 21. In this case, the transport robots 22 and the replacement robots 21 are managed by common software (robot management software 52g).

### Structure of Management Device

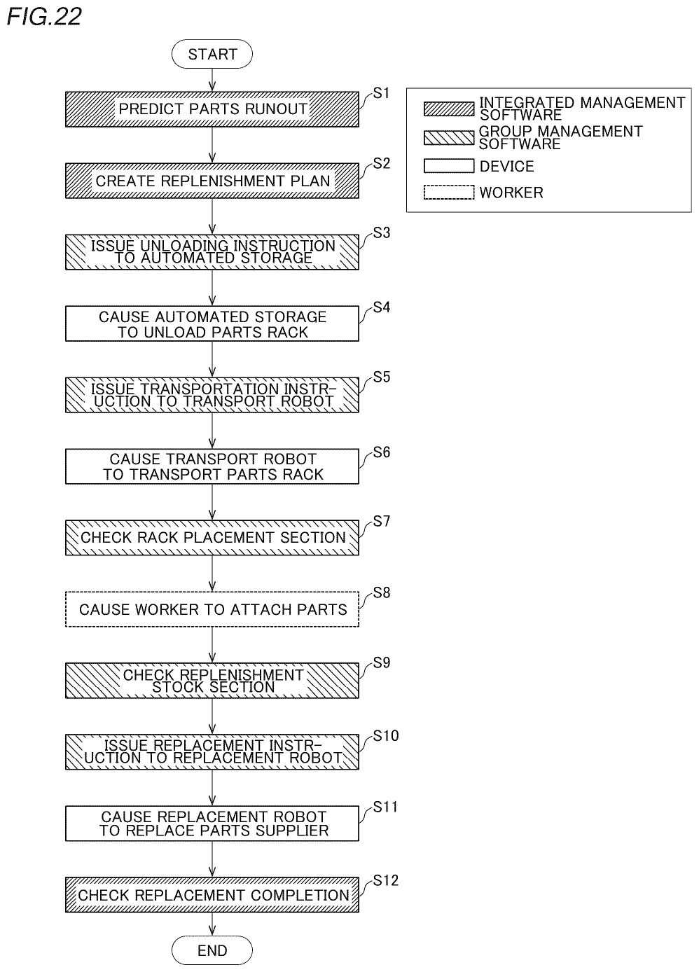

A control process of parts replenishment by the management device 50 is now described with reference to FIGS. 22 to 27.

As shown in FIG. 22, in step S1, the management device 50 predicts parts runout in the parts mounting device 14 using the integrated management software 51. Specifically, the integrated management software 51 acquires the number of parts used, the remaining number of parts, and a line operational status (an operational status such as in operation, stopped, or under maintenance) based on the information of the mounting line management software 52f. Then, the integrated management software 51 predicts parts runout based on the number of parts used, the remaining number of parts, and the line operational status.

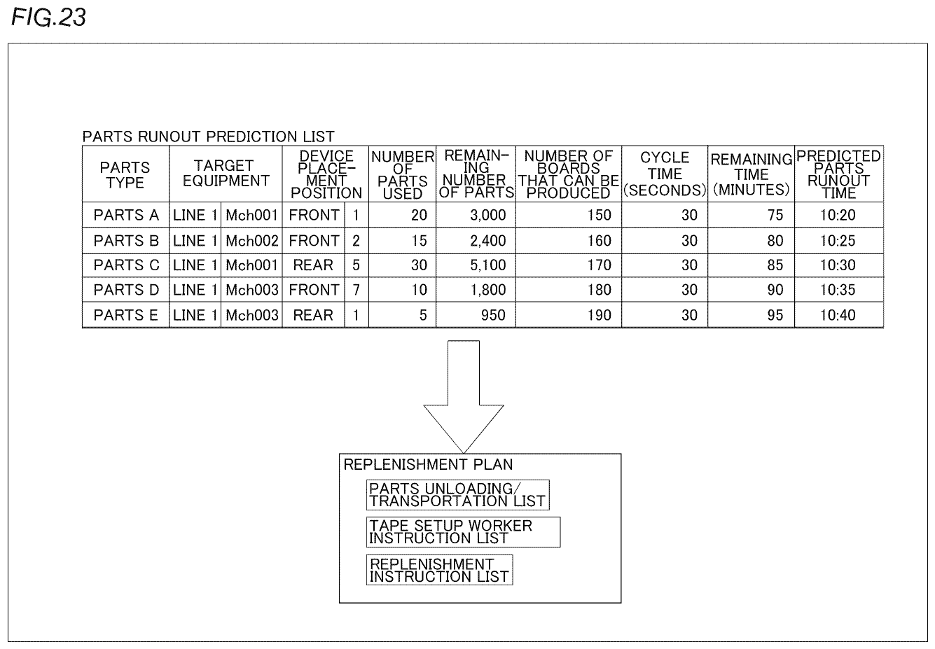

At this time, as shown in FIG. 23, the management device 50 creates a parts runout prediction list. The parts runout prediction list includes information on a parts type, target equipment, a device placement position, the number of parts used, the remaining number of parts, the number of boards that can be produced, a cycle time, a remaining time, and a predicted parts runout time. The information on a parts type represents the type of parts to be depleted. The information on target equipment represents the parts mounting device 14 that will run out of the parts. The information on a device placement position represents the parts placement position (placement lane 14b) in the parts mounting device 14 that will run out of the parts. The information on the number of parts used represents the number of parts used per board. The remaining number of parts represents the current remaining number of parts. The information on the number of boards that can be produced represents the number of boards S that can be produced with the current remaining number of parts. The number of boards that can be produced can be obtained by (remaining number of parts/number of parts used). The information on a cycle time represents the time required to produce one board. The information on a remaining time represents a period of time until parts runout occurs. The remaining time can be obtained by (number of boards that can be produced×cycle time). The information on a predicted parts runout time represents a time at which parts runout is predicted to occur. The predicted parts runout time can be obtained by (current time+remaining time).

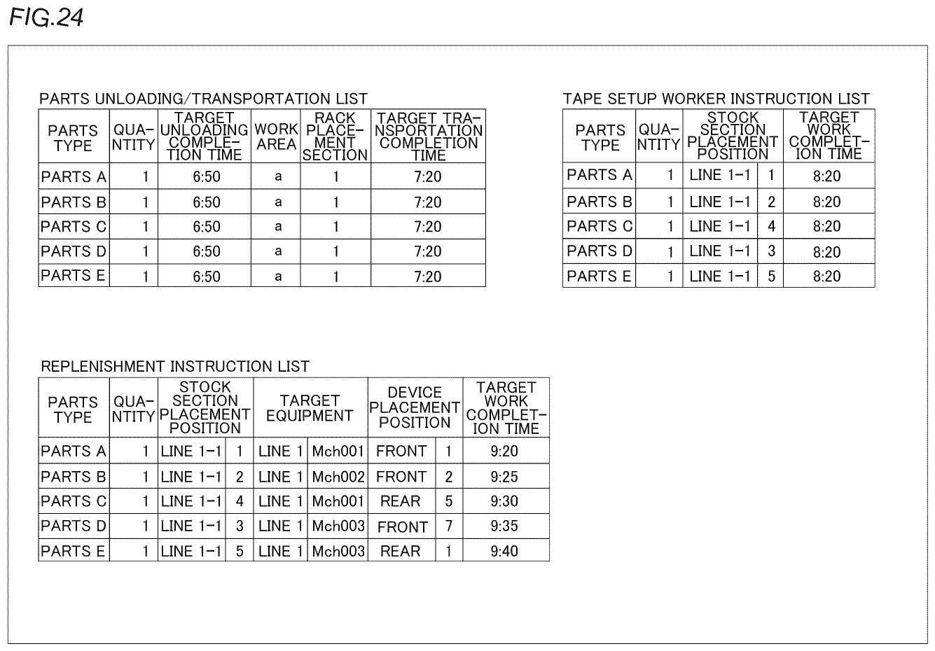

As shown in FIG. 22, in step S2, the management device 50 creates a plan for replenishing the parts mounting device 14 with the parts based on information (parts runout prediction list) regarding a time at which the parts mounting device 14 runs out of the parts using the integrated management software 51. In this embodiment, as shown in FIGS. 23 and 24, the integrated management software 51 creates the replenishment plan including target work completion times for the robots 20 (the replacement robot 21 and the transport robot 22), the automated storage 40, and the worker W by performing back calculation from the time at which the parts mounting device 14 runs out of the parts based on the work times of the robots 20 (the replacement robot 21 and the transport robot 22), the automated storage 40, and the worker W.

Specifically, the integrated management software 51 calculates the unloading work time required for the automated storage 40 to unload the parts rack 70, the transportation work time required for the transport robot 22 to transport the parts rack 70, the attachment work time required for the worker W to attach the reel R to the main body 60a of the parts supplier 60, and the replacement work time required for the replacement robot 21 to replace the parts supplier 60 based on the parts runout prediction list.

Then, the integrated management software 51 sets the target work completion times for the replacement robot 21, the transport robot 22, the automated storage 40, and the worker W by performing back calculation from the time at which the parts mounting device 14 runs out of the parts based on the calculated work times. In an example shown in FIG. 24, the time approximately 3.5 hours before the parts runout time is set as the target work completion time for the automated storage 40, the time approximately 3 hours before the parts runout time is set as the target work completion time for the transport robot 22, the time approximately 2 hours before the parts runout time is set as the target work completion time for the worker W, and the time approximately 1 hours before the parts runout time is set as the target work completion time for the replacement robot 21.

The integrated management software 51 may set the target work completion times for the replacement robot 21, the transport robot 22, the automated storage 40, and the worker W by performing back calculation based on predetermined fixed values without calculating the work times. For example, the integrated management software 51 may set the time approximately 3.5 hours (fixed value) before the parts runout time as the target work completion time for the automated storage 40, the time approximately 3 hours (fixed value) before the parts runout time as the target work completion time for the transport robot 22, the time approximately 2 hours (fixed value) before the parts runout time as the target work completion time for the worker W, and the time approximately 1 hours (fixed value) before the parts runout time as the target work completion time for the replacement robot 21 without calculating the work times.

In this embodiment, the integrated management software 51 creates a work group for a parts replacement round of the replacement robot 21, and creates a replenishment plan for the created work group. In examples shown in FIGS. 23 and 24, “parts A”, “parts B”, “parts C”, “parts D”, and “parts E” are parts that the replacement robot 21 replaces in one visit, and thus a work group of these five types of parts has been created. The integrated management software 51 creates a replenishment plan for each work group.

The replenishment plan includes a parts unloading/transportation list, a tape setup worker instruction list, and a replenishment instruction list. The parts unloading/transportation list is instruction information on parts replenishment to the automated storage management software 52a (automated storage 40) and the transport robot management software 52c (transport robot 22). The parts unloading/transportation list includes information on a parts type, a quantity, a target unloading completion time, a work area, a rack placement section, and a target transportation completion time. The information on a parts type represents the type of parts to be depleted. The information on a quantity represents the number of parts (reels R). The target unloading completion time represents the target work completion time for the automated storage 40. The information on a work area represents the work area AR2 of a transportation destination. The information on a rack placement section represents the rack placement section 32a of a transportation destination. The information on a target transportation completion time represents the target work completion time for the transport robot 22.

The tape setup worker instruction list is instruction information on parts replenishment to the worker W and the stock section management software 52d (the replenishment stock section 31a and the collection stock section 31b). The tape setup worker instruction list includes information on a parts type, a quantity, a stock section placement position, and a target work completion time. The information on a parts type represents the type of parts to be depleted. The information on a quantity represents the number of parts (reels R). The information on a stock section placement position represents the placement lane 31ab of the replenishment stock section 31a of a placement destination. The target work completion time represents the target work completion time for the worker W.

The replenishment instruction list is instruction information on parts replenishment to the replacement robot management software 52e (replacement robot 21). The replenishment instruction list includes information on a parts type, a quantity, a stock section placement position, target equipment, a device placement position, and a target work completion time. The information on a parts type represents the type of parts to be depleted. The information on a quantity represents the number of parts (reels R). The information on a stock section placement position represents the placement lane 31ab of the replenishment stock section 31a of a placement destination. The information on target equipment represents the parts mounting device 14 that will run out of the parts. The information on a device placement position represents the parts placement position (placement lane 14b) in the parts mounting device 14 that will run out of the parts. The target work completion time represents the target work completion time for the replacement robot 21.

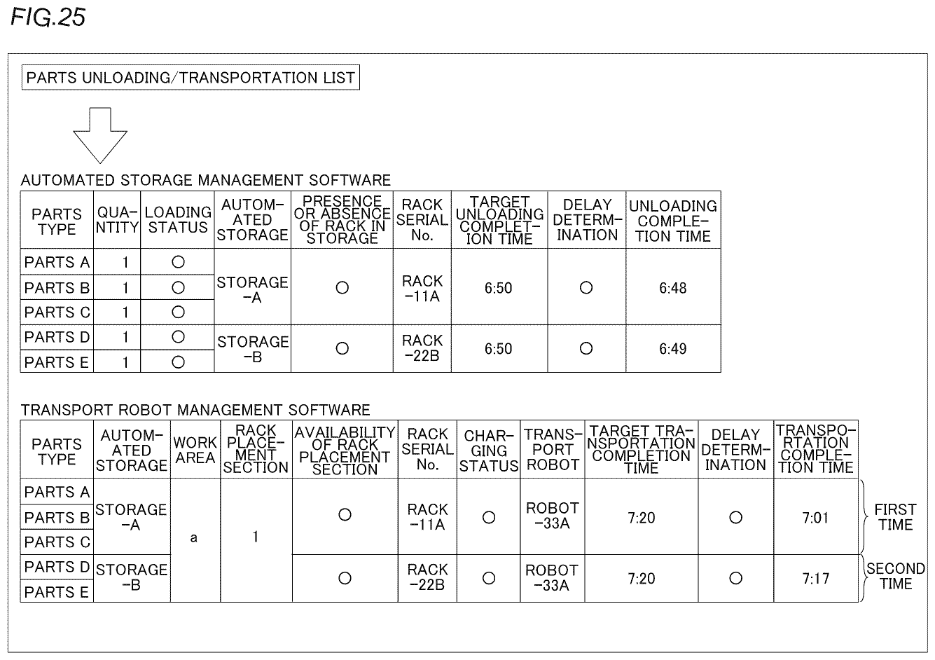

Then, as shown in FIG. 22, in step S3, the management device 50 issues an unloading instruction to the automated storage 40 using the automated storage management software 52a. Specifically, as shown in FIG. 25, the automated storage management software 52a issues an unloading instruction to the automated storage 40 and manages unloading of the automated storage 40, based on the parts unloading/transportation list. The automated storage management software 52a checks the type of parts to be unloaded, the completion status of the work of loading the parts to be unloaded, and the presence or absence of the parts rack 70 in the automated storage 40 based on the parts unloading/transportation list. The automated storage management software 52a also specifies the automated storage 40 from which the parts rack 70 is to be unloaded and the parts rack 70 to be unloaded from the automated storage 40, and issues an unloading instruction to the automated storage 40 to unload the parts rack 70 by the target unloading completion time. In an example shown in FIG. 25, the automated storages 40, a “storage-A” and a “storage-B”, are specified as the automated storages 40 from which the parts racks 70 are to be unloaded. Furthermore, the parts racks 70, a “rack-11A” and a “rack-22B”, are specified as the parts racks 70 to be unloaded from the automated storages 40. The automated storage management software 52a manages an unloading completion time and makes a delay determination. When a delay is detected by the delay determination, the automated storage management software 52a notifies the worker W as a manager of a warning.

Then, as shown in FIG. 22, in step S4, the automated storage 40 unloads the parts rack 70. In step S4, the automated storage 40 specified by the automated storage management software 52a causes the parts rack 70 specified by the automated storage management software 52a to hold the parts specified by the automated storage management software 52a, and unloads the parts rack 70 holding the parts.

In step S5, the management device 50 issues a transportation instruction to the transport robot 22 using the transport robot management software 52c. Specifically, as shown in FIG. 25, the transport robot management software 52c issues a transportation instruction to the transport robot 22 and manages transportation of the transport robot 22, based on the parts unloading/transportation list. The transport robot management software 52c checks the type of parts to be unloaded, the work area AR2 of a transportation destination, and the rack placement section 32a of a transportation destination based on the parts unloading/transportation list. Furthermore, the transport robot management software 52c checks the automated storage 40 of a transportation source, the parts rack 70 to be unloaded from the automated storage 40 of a transportation source, and the completion status of the unloading work of the automated storage 40 of a transportation source based on the information of the automated storage management software 52a. Moreover, the transport robot management software 52c checks the availability of the rack placement section 32a of a transportation destination based on the information of the rack placement section management software 52b.

The transport robot management software 52c checks an available transport robot 22, the charging status of the battery 22e of the available transport robot 22, and an available movement route. Then, the transport robot management software 52c specifies the transport robot 22 that transports the parts rack 70, and issues a transportation instruction to the transport robot 22 to transport the parts rack 70 by the target transportation completion time. In the example shown in FIG. 25, the transport robot 22 of “robot-33A” is specified as the transport robot 22 that transports the parts rack 70. Furthermore, in the example shown in FIG. 25, one transport robot 22 of “robot-33A” transports the parts rack 70 twice, but each of two transport robots 22 may transport the parts rack 70 once. The transport robot management software 52c manages a transportation completion time and makes a delay determination. When a delay is detected by the delay determination, the transport robot management software 52c notifies the worker W as a manager of a warning.

Then, as shown in FIG. 22, in step S6, the transport robot 22 transports the parts rack 70. In step S6, the transport robot 22 specified by the transport robot management software 52c moves in front of the automated storage 40 specified by the transport robot management software 52c. Then, the transport robot 22 receives the parts rack 70 unloaded from the automated storage 40 using the receiving unit 22b. Then, the transport robot 22 transports the received parts rack 70 to the rack placement section 32a specified by the transport robot management software 52c.

In step S7, the management device 50 checks the rack placement section 32a using the rack placement section management software 52b. In step S7, the rack placement section management software 52b checks the presence or absence of the parts rack 70 on the rack placement section 32a based on the result of detection of the parts rack 70 by the rack presence/absence detector 32ad of the rack placement section 32a.

In step S8, the worker W performs work to attach the reel R to the main body 60a of the parts supplier 60. In step S9, the management device 50 checks the replenishment stock section 31a using the stock section management software 52d.

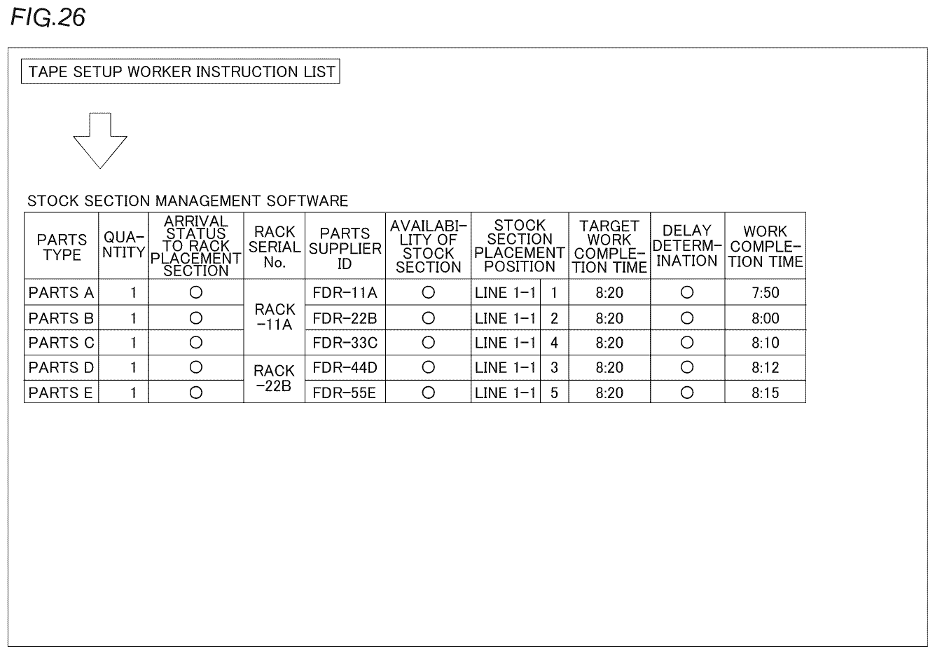

Specifically, as shown in FIG. 26, the stock section management software 52d issues a work instruction to the worker W and manages placement of the parts supplier 60 in the replenishment stock section 31a based on the tape setup worker instruction list. The stock section management software 52d checks the type of parts to be placed in the replenishment stock section 31a, the number of parts to be placed in the replenishment stock section 31a, and the placement lane 31ab of the replenishment stock section 31a of a placement destination based on the tape setup worker instruction list. The stock section management software 52d also checks the arrival status of the parts rack 70 to the rack placement section 32a based on the information of the rack placement section management software 52b. Furthermore, the stock section management software 52d checks the availability of the replenishment stock section 31a based on the result of communication with the parts supplier 60 by the parts supplier communicator 31ah of the replenishment stock section 31a. That is, the stock section management software 52d, together with the replenishment stock section 31a, performs a placement location management to manage the presence or absence and the placement location of the parts supplier 60 in the replenishment stock section 31a.

The stock section management software 52d specifies the ID of the parts supplier 60 holding the parts (reel R), and issues a work instruction to the worker W to place the parts supplier 60 by the target work completion time. The stock section management software 52d issues a work instruction to the worker W by displaying information as shown in FIG. 26 on a monitor provided in the work area AR2, for example.

The worker W acquires the reel R holding the parts specified by the stock section management software 52d from the parts rack 70 transported from the automated storage 40 by the transport robot 22. Then, the worker W prepares the parts supplier 60 to be placed in the replenishment stock section 31a by performing work to attach the acquired reel R to the main body 60a of the parts supplier 60 with the ID specified by the stock section management software 52d. Then, the worker W performs work to place the prepared parts supplier 60 in the placement lane 31ab of the replenishment stock section 31a specified by the stock section management software 52d.

The stock section management software 52d manages a work completion time (placement completion time) and makes a delay determination. When a delay is detected by the delay determination, the stock section management software 52d notifies the worker W as a manager of a warning.

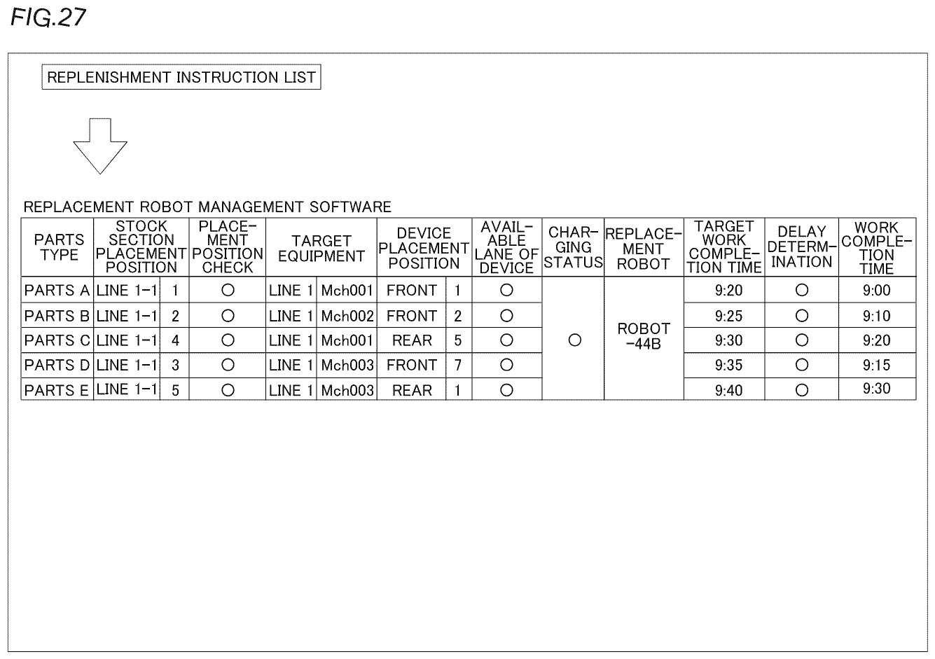

In step S10, the management device 50 issues a replacement instruction to the replacement robot 21 using the replacement robot management software 52e. Specifically, as shown in FIG. 27, the replacement robot management software 52e issues a replacement instruction to the replacement robot 21 and manages replacement of the replacement robot 21 based on the replenishment instruction list. The replacement robot management software 52e checks the type of parts to be replaced, the placement lane 31ab of the replenishment stock section 31a of a transportation source, and the placement lane 14b of the parts mounting device 14 of a transportation destination based on the replenishment instruction list. The replacement robot management software 52e also checks the placement status of the parts supplier 60 in the replenishment stock section 31a of a transportation source based on the information of the stock section management software 52d. Furthermore, the replacement robot management software 52e checks the availability of the placement lane 14b of the parts mounting device 14 of a transportation destination based on the information of the mounting line management software 52f.

The replacement robot management software 52e checks an available replacement robot 21, the charging status of the battery 21h of the available replacement robot 21, and an available circulation route. Then, the replacement robot management software 52e specifies the replacement robot 21 that transports and replaces the parts supplier 60, and issues a transportation instruction to the replacement robot 21 to transport and replace the parts supplier 60 by the target work completion time. In an example shown in FIG. 27, the replacement robot 21 of “robot-44B” is specified as the replacement robot 21 that transports and replaces the parts supplier 60. Furthermore, the replacement robot management software 52e manages a work completion time (replacement completion time) and makes a delay determination. When a delay is detected by the delay determination, the replacement robot management software 52e notifies the worker W as a manager of a warning.

Then, as shown in FIG. 22, in step S11, the replacement robot 21 replaces the parts supplier 60. In step S11, the replacement robot 21 specified by the replacement robot management software 52e moves in front of the replenishment stock section 31a specified by the replacement robot management software 52e. Then, the replacement robot 21 acquires the parts supplier 60 from the placement lane 31ab of the replenishment stock section 31a specified by the replacement robot management software 52e using the insertion/extraction unit 21f. Then, the replacement robot 21 transports the acquired parts supplier 60 to the placement lane 14b of the parts mounting device 14 specified by the replacement robot management software 52e and makes replacement. Furthermore, the replacement robot 21 transports and returns the parts supplier 60 collected from the parts mounting device 14 by replacement to the collection stock section 31b.

Then, in step S12, the management device 50 checks that replacement of the parts supplier 60 specified in the replenishment plan has been completed using the integrated management software 51. Then, the control process of parts replenishment by the management device 50 is terminated. The control process of parts replenishment by the management device 50 is performed at predetermined time intervals (such as every few hours), for example. Thus, the parts mounting device 14 that has run out of the parts is appropriately replenished with the parts.

In the above description, the process operations in step S3 to step S11 in the flowchart shown in FIG. 22 are described in the order of the flowchart for convenience, but to be exact, the process operations in step S3 to step S11 in the flowchart shown in FIG. 12 are not performed in the order of the flowchart, and the process operations that can be performed in parallel with each other are performed in parallel with each other.

Control Process of Warning during Parts Replenishment

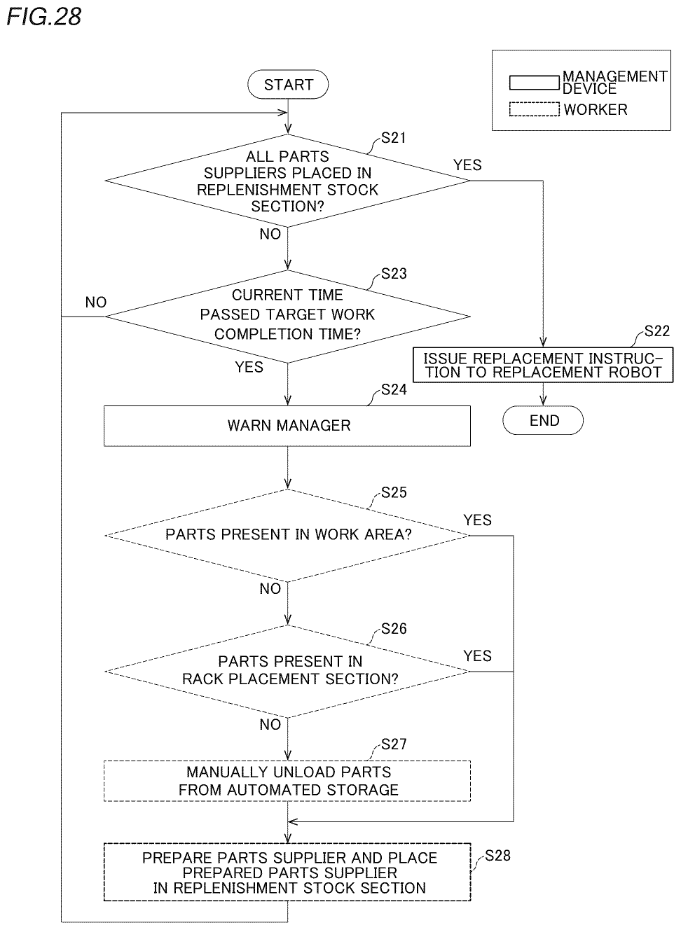

A control process of warning when the parts supplier 60 is not placed in the replenishment stock section 31a is now described based on a flowchart with reference to FIG. 28.

First, in step S21, the management device 50 determines whether or not all parts suppliers 60 scheduled to be placed in the replenishment stock section 31a have been placed. In step S21, the management device 50 determines whether or not all parts suppliers 60 scheduled to be placed in the replenishment stock section 31a have been placed in the replenishment stock section 31a, based on information on placement location management by the replenishment stock section 31a. When it is determined that all parts suppliers 60 scheduled to be placed in the replenishment stock section 31a have been placed, the process advances to step S22. Then, in step S22, the management device 50 issues a replacement instruction to the replacement robot 21. When it is determined in step S21 that all parts suppliers 60 scheduled to be placed in the replenishment stock section 31a are not placed, the process advances to step S23.

Then, in step S23, the management device 50 determines whether or not the current time has passed the target work completion time for the worker W. When it is determined that the current time has not passed the target work completion time for the worker W, the process operation in step S21 is repeated. When it is determined that the current time has passed the target work completion time for the worker W, the process advances to step S24.

Then, in step S24, the management device 50 notifies the worker W as a manager of a warning. In step S24, a warning is sent to a mobile terminal carried by the worker W as a manager, for example.

Then, in step S25, the worker W as a manager checks whether or not the parts (reel R) are present on the work desk T1 or the like in the work area AR2. When the parts (reel R) are present on the work desk T1 or the like in the work area AR2, the process advances to step S28. When the parts (reel R) are not present on the work desk T1 or the like in the work area AR2, the process advances to step S26.

Then, in step S26, the worker W as a manager checks whether or not the parts (reel R) are present in the parts rack 70 placed in the rack placement section 32a. When the parts (reel R) are present in the parts rack 70 placed in the rack placement section 32a, the process advances to step S28. When the parts (reel R) are not present in the parts rack 70 placed in the rack placement section 32a, the process advances to step S27.

Then, in step S27, the worker W as a manager performs work to manually unload the parts (reels R) from the automated storage 40. Then, the process advances to step S28.

Then, in step S28, the worker W as a manager prepares the parts supplier 60 by attaching the parts (reel R) to the main body 60a of the parts supplier 60. Then, the worker W as a manager places the prepared parts supplier 60 in the replenishment stock section 31a. Then, the process advances to step S21, and in step S21, it is determined that all parts suppliers 60 scheduled to be placed in the replenishment stock section 31a have been placed. Then, the process advances to step S22, and in step S22, a replacement instruction is issued to the replacement robot 21.

### Advantageous Effects of this Embodiment

According to this embodiment, the following advantageous effects are achieved.

According to this embodiment, as described above, the parts mounting system 100 includes the placement section 30 in the work area AR2 in which the worker W works and that is separate from the mounting area ARI to allow a plurality of parts units, which are to be transported or have been transported by the robot 20, to be placed therein or thereon. Accordingly, the placement section 30 can be provided as a buffer for the parts units, and thus the worker W is less likely to be forced to spend time to deliver the parts unit to the robot 20 or receive the parts unit from the robot 20, for example. Consequently, the worker W is relatively free to go to the restroom, take a meal break, and perform other tasks, for example, unlike a case in which the time of the worker W is greatly restricted, and thus when the parts unit is transported by the robot 20, the time of the worker W can be effectively used to improve work efficiency. Furthermore, the placement section 30 is provided in the work area AR2, and thus unlike a case in which the placement section 30 is provided in the mounting line 10, the placement section 30 can be used as a common placement section 30 for a plurality of mounting lines 10 when the plurality of mounting lines 10 are present.

According to this embodiment, as described above, the robot 20 includes the replacement robot 21 to transport the parts supplier 60 as the parts unit between the work area AR2 and the parts mounting device 14. Furthermore, the placement section 30 includes the first placement section 31 to allow a plurality of parts suppliers 60, which are to be transported or have been transported by the replacement robot 21, to be placed therein. Accordingly, the first placement section 31 can be provided as a buffer for the parts suppliers 60, and thus the worker W is not forced to spend much time to deliver the parts supplier 60 to the replacement robot 21 or receive the parts supplier 60 from the replacement robot 21, for example. Consequently, the worker W can effectively use his or her time to improve work efficiency.

According to this embodiment, as described above, the first placement section 31 includes the replenishment stock section 31a to allow a plurality of parts suppliers 60, which are to be transported from the work area AR2 to the parts mounting device 14 and supplied to the parts mounting device 14 by the replacement robot 21, to be placed therein, and the collection stock section 31b to allow a plurality of parts suppliers 60, which the replacement robot 21 has collected from the parts mounting device 14 and transported to the work area AR2, to be placed therein. Accordingly, the replenishment stock section 31a can be provided as a buffer for the parts suppliers 60 to be supplied, and thus the worker W is not forced to spend much time to deliver the parts supplier 60 to the replacement robot 21. Furthermore, the collection stock section 31b can be provided as a buffer for the collected parts suppliers 60, and thus the worker W is not forced to spend much time to receive the parts supplier 60 from the replacement robot 21. Consequently, the worker W can more effectively use his or her time to improve work efficiency. Furthermore, when the replenishment stock section 31a is provided as a buffer for the parts suppliers 60 to be supplied, the worker W can perform work to prepare the parts supplier 60 in a relatively flexible manner. Consequently, variations in the time required for the work to prepare the parts supplier 60 can be absorbed.

According to this embodiment, as described above, the first placement section 31 is operable to perform a placement location management to manage the presence or absence and the placement location of the parts supplier 60 in the first placement section 31. Accordingly, the first placement section 31 can manage the placement location of the parts supplier 60. Consequently, the progress of supplying the parts supplier 60 to the parts mounting device 14 can be managed.

According to this embodiment, as described above, the replenishment stock section 31a of the first placement section 31 includes a plurality of placement lanes 31ab, each of which allows a parts supplier 60 to be placed therein, and the parts supplier communicator 31ah provided in each of the plurality of placement lanes 31ab, and is operable to perform the placement location management by communicating with the parts supplier 60 through the parts supplier communicator 31ah. Accordingly, it can be known which parts supplier 60 is placed in which placement lane 31ab among the plurality of placement lanes 31ab through the parts supplier communicator 31ah. Consequently, the placement location of the parts supplier 60 can be easily managed by the replenishment stock section 31a of the first placement section 31.

According to this embodiment, as described above, the parts mounting system 100 is operable to notify the worker W of a warning when it is detected by the placement location management that the parts supplier 60 has not been placed in the replenishment stock section 31a of the first placement section 31 by the predetermined time before the parts mounting device 14 runs out of the parts. Accordingly, from the warning, it can be recognized that supply of the parts supplier 60 to the parts mounting device 14 is delayed. Consequently, even when supply of the parts supplier 60 to the parts mounting device 14 is delayed, the parts supplier 60 can be supplied to the parts mounting device 14 in time.

According to this embodiment, as described above, the parts mounting system 100 includes the automated storage 40 in the storage area AR3 separate from the mounting area AR1 and the work area AR2 to unload the parts rack 70 as the parts unit. Furthermore, the robot 20 includes the transport robot 22 to transport the parts rack 70 between the automated storage 40 and the work area AR2. The placement section 30 includes the second placement section 32 to allow a plurality of parts racks 70, which have been transported or are to be transported by the transport robot 22, to be placed thereon. Accordingly, the second placement section 32 can be provided as a buffer for the parts racks 70, and thus the worker W is not forced to spend much time to deliver the parts rack 70 to the transport robot 22 or receive the parts rack 70 from the transport robot 22, for example. Consequently, the worker W can effectively use his or her time to improve work efficiency.

According to this embodiment, as described above, the second placement section 32 includes the rack placement section 32a to allow a plurality of parts racks 70 holding the parts, which the transport robot 22 has transported from the automated storage 40 to the work area AR2, to be placed thereon, and the empty rack placement section 32b to allow a plurality of empty parts racks 70 not holding the parts, which are to be collected from the work area AR2 and transported to the automated storage 40 by the transport robot 22, to be placed thereon. Accordingly, the rack placement section 32a can be provided as a buffer for the parts racks 70, and thus the worker W is not forced to spend much time to receive the parts rack 70 from the transport robot 22. Furthermore, the empty rack placement section 32b can be provided as a buffer for the empty parts racks 70, and thus the worker W is not forced to spend much time to deliver the empty parts rack 70 to the transport robot 22. Consequently, the worker W can more effectively use his or her time to improve work efficiency.

According to this embodiment, as described above, the management device 50 is operable to create the plan for replenishing the parts mounting device 14 with the parts based on the information regarding the time at which the parts mounting device 14 runs out of the parts. Accordingly, the parts mounting device 14 can be replenished with the parts according to the replenishment plan in a planned manner, and thus it is possible to easily respond to parts replenishment rush, and the number of robots 20 operating to supply the parts can be optimized (minimized).

According to this embodiment, as described above, the parts mounting system 100 includes the automated storage 40 in the storage area AR3 separate from the mounting area AR1 and the work area AR2 to unload the parts unit. Furthermore, the management device 50 is operable to create the replenishment plan including the target work completion times for the robot 20, the automated storage 40, and the worker W by performing back calculation from the time at which the parts mounting device 14 runs out of the parts based on the work times of the robot 20, the automated storage 40, and the worker W. Accordingly, the robot 20, the automated storage 40, and the worker W can easily know the target work completion times based on the replenishment plan, and thus they can easily complete their work by the target work completion times. Consequently, stopping of the parts mounting device 14 due to parts runout of the parts mounting device 14 can be easily reduced or prevented.

According to this embodiment, as described above, the management device 50 is operable to create the work group for a parts replacement round of the robot 20, and create the replenishment plan for the created work group. Accordingly, the replenishment plan can be created for each work group, and thus an excessive increase in the contents of the replenishment plan can be easily reduced or prevented. Furthermore, the replenishment plan can be created for each work group, and thus the progress of the replenishment plan for each work group can be easily managed.

### Modified Examples

The embodiment disclosed this time must be considered as illustrative in all points and not restrictive. The scope of the present disclosure is not shown by the above description of the embodiment but by the scope of claims for patent, and all modifications (modified examples) within the meaning and scope equivalent to the scope of claims for patent are further included.

For example, while the example in which one mounting area, one storage area, and two work areas are provided has been shown in the aforementioned embodiment, the present disclosure is not restricted to this. In the present disclosure, the number of mounting areas, the number of work areas, and the number of storage areas may be any number.

While the example in which the robots include the replacement robot and the transport robot has been shown in the aforementioned embodiment, the present disclosure is not restricted to this. For example, the robots may include only one of the replacement robot and the transport robot. Alternatively, the robots may include a robot other than the replacement robot and the transport robot.

While the example in which the placement sections include the first placement section and the second placement section has been shown in the aforementioned embodiment, the present disclosure is not restricted to this. For example, the placement sections may include only one of the first placement section and the second placement section. Alternatively, the placement sections may include a placement section other than the first placement section and the second placement section.

While the example in which the first placement section includes the replenishment stock section and the collection stock section has been shown in the aforementioned embodiment, the present disclosure is not restricted to this. For example, the first placement section may include only one of the replenishment stock section and the collection stock section. Alternatively, the first placement section may include a stock section other than the replenishment stock section and the collection stock section.

While the example in which the second placement section includes the rack placement section and the empty rack placement section has been shown in the aforementioned embodiment, the present disclosure is not restricted to this. For example, the second placement section may include only one of the rack placement section and the empty rack placement section. Alternatively, the second placement section may include a rack section other than the rack placement section and the empty rack placement section.

While the example in which the replenishment stock section can perform the placement location management has been shown in the aforementioned embodiment, the present disclosure is not restricted to this. For example, the replenishment stock section may not be able to perform the placement location management.

While the example in which the integrated management software and the plurality of pieces of group management software are provided as software that manages the parts mounting system has been shown in the aforementioned embodiment, the present disclosure is not restricted to this. In the present disclosure, the software that manages the parts mounting system may have any structure as long as the same can manage the parts mounting system.

While the example in which the management device creates the work group for one parts replacement round of the replacement robot, and creates the replenishment plan for the created work group has been shown in the aforementioned embodiment, the present disclosure is not restricted to this. For example, the management device may create a work group for a plurality of parts replacement rounds of the replacement robot, and create a replenishment plan for the created work group.

What is claimed is:

1. A parts mounting system comprising:
a parts mounting device in a mounting area to mount parts on a board;
a robot to transport a parts unit operable to hold the parts; and
a placement section in a work area in which a worker works, the work area being separate from the mounting area and a storage area, to allow a plurality of parts units to be placed therein or thereon, the plurality of parts units being to be transported or having been transported by the robot,
wherein
the robot includes a first robot to transport a parts supplier as the parts unit between the work area and the parts mounting device;
the work area is an area in which the worker performs work to attach a reel operable to hold the parts to the parts supplier or the worker performs work to remove the reel from the parts supplier; and
the placement section includes a first placement section in the work area to allow a plurality of parts suppliers to be placed therein, the plurality of parts suppliers being to be transported or having been transported by the first robot.

2. (canceled)

3. The parts mounting system according to claim 1, wherein
the first placement section includes a replenishment stock section to allow the plurality of parts suppliers to be placed therein, the plurality of parts suppliers being to be transported from the work area to the parts mounting device and supplied to the parts mounting device by the first robot, the plurality of parts suppliers being to be used, and a collection stock section to allow a plurality of used parts suppliers to be placed therein, the plurality of used parts suppliers having been collected from the parts mounting device and transported to the work area by the first robot.

4. The parts mounting system according to claim 1, wherein the first placement section is operable to perform a placement location management to manage a presence or absence and a placement location of the parts supplier in the first placement section.

5. The parts mounting system according to claim 4, wherein the first placement section includes a plurality of placement lanes, each to allow the parts supplier to be placed therein, and a parts supplier communicator in each of the plurality of placement lanes, and is operable to perform the placement location management by communicating with the parts supplier through the parts supplier communicator.

6. The parts mounting system according to claim 4, operable to notify the worker of a warning when the placement location management determines that the parts supplier has not been placed in the first placement section by a predetermined time before the parts mounting device runs out of the parts.

7. The parts mounting system according to claim 1, further comprising:
an automated storage in the storage area separate from the mounting area and the work area to unload a parts rack as the parts unit; wherein
the robot includes a second robot to transport the parts rack between the automated storage and the work area; and
the placement section includes a second placement section to allow a plurality of parts racks to be placed thereon, the plurality of parts racks having been transported or being to be transported by the second robot.

8. The parts mounting system according to claim 7, wherein the second placement section includes a rack placement section to allow the plurality of parts racks holding the parts to be placed thereon, the plurality of parts racks having been transported from the automated storage to the work area by the second robot, and an empty rack placement section to allow a plurality of empty parts racks not holding the parts to be placed thereon, the plurality of empty parts racks being to be collected from the work area and transported to the automated storage by the second robot.

9. The parts mounting system according to claim 1, operable to create a plan for replenishing the parts mounting device with the parts based on information regarding a time at which the parts mounting device runs out of the parts.

10. The parts mounting system according to claim 9, further comprising:
an automated storage in the storage area separate from the mounting area and the work area to unload the parts unit; wherein
the parts mounting system is operable to calculate work times of the robot, the automated storage, and the worker, and create the plan including target work completion times for the robot, the automated storage, and the worker by performing back calculation from the time at which the parts mounting device runs out of the parts based on calculated times.

11. The parts mounting system according to claim 9, operable to create a work group for a plurality of parts replacement rounds of the robot, and create the plan for a created work group.

12. The parts mounting system according to claim 3, wherein the first placement section is operable to perform a placement location management to manage a presence or absence and a placement location of the parts supplier in the first placement section.

13. The parts mounting system according to claim 5, operable to notify the worker of a warning when the placement location management determines that the parts supplier has not been placed in the first placement section by a predetermined time before the parts mounting device runs out of the parts.

14. The parts mounting system according to claim 3, further comprising:
an automated storage in the storage area separate from the mounting area and the work area to unload a parts rack as the parts unit; wherein
the robot includes a second robot to transport the parts rack between the automated storage and the work area; and
the placement section includes a second placement section to allow a plurality of parts racks to be placed thereon, the plurality of parts racks having been transported or being to be transported by the second robot.

15. The parts mounting system according to claim 4, further comprising:
an automated storage in the storage area separate from the mounting area and the work area to unload a parts rack as the parts unit; wherein
the robot includes a second robot to transport the parts rack between the automated storage and the work area; and
the placement section includes a second placement section to allow a plurality of parts racks to be placed thereon, the plurality of parts racks having been transported or being to be transported by the second robot.

16. The parts mounting system according to claim 5, further comprising:
an automated storage in the storage area separate from the mounting area and the work area to unload a parts rack as the parts unit; wherein
the robot includes a second robot to transport the parts rack between the automated storage and the work area; and
the placement section includes a second placement section to allow a plurality of parts racks to be placed thereon, the plurality of parts racks having been transported or being to be transported by the second robot.

17. The parts mounting system according to claim 3, operable to create a plan for replenishing the parts mounting device with the parts based on information regarding a time at which the parts mounting device runs out of the parts.

18. The parts mounting system according to claim 4, operable to create a plan for replenishing the parts mounting device with the parts based on information regarding a time at which the parts mounting device runs out of the parts.

19. The parts mounting system according to claim 5, operable to create a plan for replenishing the parts mounting device with the parts based on information regarding a time at which the parts mounting device runs out of the parts.

20. The parts mounting system according to claim 10, operable to create a work group for a plurality of parts replacement rounds of the robot, and create the plan for a created work group.
